(19) United States
(12) Patent Application Publication
(10) Pub. No.: US 2009/0202919 A1
(43) Pub. Date: Aug. 13, 2009

(54) Apparatus and methods for threshold control of photopolymerization for holographic data storage using at least two wavelengths

(75) Inventors: David A. Waldman, Concord, MA (US); Eric S. Kolb, Acton, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: STX Aprilis, Inc., Maynard, MA (US)

(21) Appl. No.: 12/288,843

(22) Filed: Oct. 23, 2008

Related U.S. Application Data
(60) Provisional application No. 60/999,999, filed on Oct. 23, 2007.
(60) Provisional application No. 61/189,729, filed on Aug. 22, 2008.

(51) Int. Cl. G03F 7/00

(52) U.S. Cl. 430/2

(57) ABSTRACT

A polymerizable media, including holographic recording media, and methods of use of the same. The media comprises at least one monomer or oligomer which undergoes polymerization to form a polymer; a compound, which absorbs actinic radiation of a first wavelength and forms a sensitizer which absorbs actinic radiation of a second wavelength; and an initiator, which, in combination with the sensitizer, initiates polymerization of the at least one monomer or oligomer when said sensitizer is exposed to actinic radiation of the second wavelength.

### RELATED APPLICATIONS

This application claims the benefit of U.S. Provisional Application No. 60/999,999, filed on Oct. 23, 2007, and U.S. Provisional Application No. 61/189,729, filed on Aug. 22, 2008. The entire teachings of the above applications are incorporated herein by reference.

### BACKGROUND OF THE INVENTION

As the need for increased data storage changes, the search for higher density and faster access for data storage technologies also increases. One of these, holographic data storage, provides the promise for fast access times to higher density data. In holographic data storage, information is recorded as an ensemble of interference fringe patterns formed by the intersection of two coherent energy sources. Typically, coherent light beams from lasers are utilized to perform the addressing, namely writing and reading of the data from the storage media by directing these beams at a specific region on the surface of the media. In the prior art, interference fringes are formed within a holographic recording media comprising a homogeneous mixture of monomer or oligomer and a binder and a polymerization initiator. In the holographic media, this initiation followed by polymerization occurs in the light areas of the interference fringe pattern. In this process, monomer or oligomer diffuses into the light areas of the fringe structure to be incorporated into the growing polymer chains. Polymerization induced chemical segregation, in the case of a diffusible binder, drives the binder into the dark regions of the fringe structure. Since the monomer or oligomer and the binder have differing index of refraction an index modulation is achieved during the exposure process.

The recording media is made sensitive to actinic radiation of a desired energy level (wavelength) by the incorporation of a photo initiator. The photo initiator may absorb light energy directly or may be sensitized to a desired wavelength or energy of irradiation by incorporation of a sensitizing dye. The normal polymerization procedure is to irradiate the photopolymer with photons having energy which will begin the polymerization process. The reaction sequence associated with this process is complex. A simplified, but reasonably good model is as follows: the sensitizing dye compound is first exited by a photon of proper energy, and then the excited dye transfers energy to the initiator, photo acid generator, (PAG), for example, to provide an activated initiator species, or the excited state dye reacts with the initiator via a oxidation-reduction process to form an initiative species. In either case the initiative species or activated initiator then combines with a monomer, which begins a chain reaction with additional monomers to result in polymerization.

In the prior art the sensitizer dyes used are linear absorbers at the exposure wavelengths for recordation. These sensitizer dyes work by converting light energy into chemical initiative species at some quantum efficiency associated with the molecular make-up of the dye molecule and its surroundings. The use of said dye in conjunction with a PAG leads to holographic media with high recording sensitivity as well as other favorable characteristics such as bleaching. The utilization of a linear absorber yields a holographic or photo-polymerizable medium with a linear response to actinic radiation. In such a system the initiation of polymerization, the strength of the hologram and the amount of monomer or oligomer polymerized after a particular photo-initiated event is proportional to the amount of actinic radiation or exposure fluence the media has received in a location or storage volume.

One problem with utilization of linear absorbers in a holographic media for data storage is evident when angle multiplexing volume holograms in thick media. Holograms are recorded in a photopolymer medium with a finite angle between the reference beam and the signal beam, this angle generally referred to as the inter beam angle. Many holograms can be recorded in the same volume location, such as by changing the inter beam angle for each recording or by changing the angle of incidence of either beam with respect to the volume location in the medium. Each angle combination between the signal beam and the reference beam represents a unique hologram. The process of recording a grouping of holograms in the same volume element is referred to co-locational multiplexing. The larger the dynamic range the greater the number of holograms can be recorded in the particular location and thus a larger data storage density. (Typically the dynamic range in a photopolymer medium is proportional to the amount of active monomer and or oligomer available for reaction (polymerization)) and the magnitude of the difference in the index of refraction between the monomer and the binder. In one method of recording, after fully consuming the dynamic range in a particular location, hologram recording can commence in a new location and so on until all the dynamic range in the media is fully consumed. Ideally, each storage location is arranged in a closest packed geometry to optimally use the media's dynamic range and thus maximize the storage density. The recordation of holograms only takes place in the beam overlap region in the hologram recording material (i.e. in the interference fringe pattern). Outside the region of the interference fringe pattern, where the reference and signal beam impinge on or in the recording material but do not overlap, photo-polymerization is initiated at a rate or amount associated with the photon flux and the quantum efficiency of initiation. This unintended polymerization consumes photo-initiator and monomers/oligomers thus wasting the dynamic range in the volume element surrounding a particular storage location. This unintended polymerization has a significant impact on the overall storage density achievable in a holographic media and is exacerbated as the thickness of the recording material increases.

One proposed solution to this problem is to include an inhibitor in the recording medium. The inhibitor prevents premature polymerization and keeps the media in an inactive state by consuming or quenching initiating species as they are formed, either by reacting with the photo initiator or by reacting/quenching growing chain ends, thereby limiting or preventing polymerization and preventing formation of holograms. In order to form holograms the inhibitor needs to be removed or otherwise chemically reacted or depleted. After the inhibitor is depleted in a region then the initiator can then react with monomer(s) to effect polymerization and record holograms. Once the threshold exposure is achieved, depleting an inhibitor in the storage location, the hologram recording process can initiate. In such a system, especially for thick media, exposure outside the overlap region of the recording beams is significant and will lead to premature consumption of inhibitor. Without sophisticated tracking of the amount of exposure in the regions outside the overlap regions it will remain difficult to properly track the amount of inhibitor in regions abutting a storage location, and the degree of exposure to deplete inhibitor will fluctuate during the exposure process. Additionally, as an inhibitor is depleted, so to is the initiator used to initiate polymerization for hologram recording. This will reduce the amount of photo-initiator available for hologram recording and in turn reduce the recording sensitivity, and, further, will cause fluctuation in the amount of photo-initiator.

One approach to achieve high storage density is to use a non-linear absorber as the photo-sensitizer in the photo-polymerizable medium. In such a system a two-photon process or multi-photon process, is used to create a localized region for polymerization. The polymerization region is localized due to the nonlinear absorption properties of the two-photon dye, where the absorption probability depends quadratically on light intensity. Thus a two-photon excitation provides a means of activating chemical or physical processes with high spatial resolution. Unfortunately, the nonlinear nature of the absorption makes the use of a two-photon absorber unsuitable for display holography or for data page recoding, where the hologram is recorded uniformly throughout the storage volume, and, further, the non linear nature equates to low recording sensitivity.

### SUMMARY OF THE INVENTION

The present invention relates to a polymerizable media in which a sensitizer is produced in situ as well as to the methods of use of such a polymerizable media.

In one embodiment, the present invention is a polymerizable media, comprising at least one monomer or oligomer which undergoes polymerization to form a polymer; a compound, which absorbs actinic radiation of a first wavelength and forms a sensitizer which absorbs actinic radiation of a second wavelength; and an initiator, which, in combination with the sensitizer, initiates polymerization of the at least one monomer or oligomer when said sensitizer is exposed to actinic radiation of the second wavelength.

In another embodiment, the present invention is a method of polymerizing a polymerizable media. The polymerizable media comprises at least one monomer or oligomer which undergoes polymerization to form a polymer; a compound, which absorbs actinic radiation of a first wavelength and forms a sensitizer which absorbs actinic radiation of a second wavelength; and an initiator, which, in combination with the sensitizer, initiates polymerization of the at least one monomer or oligomer when said sensitizer is exposed to actinic radiation of the second wavelength. The method comprises (a) exposing a first location in the polymerizable media to actinic radiation of the first wavelength, thereby forming the sensitizer from the compound; and (b) exposing the first location in the polymerizable media to actinic radiation of the second wavelength, thereby initiating polymerization of the at least one monomer or oligomer.

In another embodiment, the present invention is a method of recording a hologram in a holographic recording media (HRM). The HRM comprises at least one monomer or oligomer which undergoes polymerization; a binder; a compound, which absorbs actinic of a first wavelength and forms a sensitizer which absorbs actinic radiation of a second wavelength; and an initiator, which, in combination with the sensitizer initiates polymerization of the at least one monomer or oligomer, when said sensitizer is exposed to actinic radiation of the second wavelength. The method comprises (a) exposing a first storage location in the holographic recording media to a beam actinic radiation of the first wavelength, thereby forming a sensitizer from the compound, said sensitizer absorbing actinic radiation of a second wavelength; and (b) directing a reference beam of coherent light of the second wavelength and an object beam of coherent light of the second wavelength at the first storage location, thereby forming an interference pattern at the first storage location between the object beam and the reference beam, initiating polymerization of the at least one monomer or oligomer and thereby recording the interference pattern as a hologram within said first storage location.

In another embodiment, the present invention is a method of recording a micrograting hologram in a holographic recording media (HRM) that includes at least one monomer or oligomer which undergoes polymerization; a binder; a compound, which absorbs actinic of a first wavelength and forms a sensitizer which absorbs actinic radiation of a second wavelength; and an initiator, which, in combination with the sensitizer initiates polymerization of the at least one monomer or oligomer, when said sensitizer is exposed to actinic radiation of the second wavelength. The method comprises (a) exposing a first storage location in the holographic recording media to actinic radiation of the first wavelength, thereby forming a sensitizer from the compound, said sensitizer absorbing electromagnetic radiation of a second wavelength, said first storage location being located in a portion of the depth of the HRM; and (b) directing a reference beam of the second wavelength and an object beam of the second wavelength at the first storage location, thereby forming an interference pattern at the first storage location between the object beam and the reference beam, and initiating polymerization of the at least one monomer or oligomer in the first storage location and thereby recording the interference pattern as a hologram within said first storage location. As used herein, the phrase “a portion of the depth of the HRM” means a fraction of the thickness of the HRM. The fraction can be any number between 0 and 1, e.g. 10%, 20%, 30%, 40%, 50%, 60%, 70%, 80% or 90%.

In another embodiment, the present invention is a method of recording a hologram, in a holographic recording media (HRM). The HRM includes at least one monomer or oligomer which undergoes polymerization; a binder; a compound, which absorbs actinic of a first wavelength and forms a sensitizer which absorbs actinic radiation of a second wavelength; and an initiator, which, in combination with the sensitizer initiates polymerization of the at least one monomer or oligomer, when said sensitizer is exposed to actinic radiation of the second wavelength. The method comprises (a) exposing a first storage location in the holographic recording media (HRM) to a beam of actinic radiation of the first wavelength, thereby forming a sensitizer from the compound, said sensitizer absorbing electromagnetic radiation of a second wavelength; and (b) directing a reference beam of coherent light of the second wavelength and an object beam of coherent light of the second wavelength at the first storage location in the holographic recording media (HRM), thereby forming an interference pattern at the first storage location between the object beam and the reference beam, initiating polymerization of the at least one monomer or oligomer and recording the interference pattern therefrom as a hologram within said first storage location. Preferably, the beam of actinic radiation of the first wavelength, the reference beam, or the object beam is each independently generated by a tunable source.

In another embodiment, the present invention is an optical article. The optical article comprises two or more substrates; and a holographic recording medium (HRM) therebetween. The HRM includes at least one monomer or oligomer which undergoes polymerization; a compound, which absorbs actinic radiation of a first wavelength and forms a sensitizer which absorbs actinic radiation of a second wavelength; and an initiator, which, in combination with the sensitizer, initiates polymerization of the at least one monomer or oligomer when said sensitizer is exposed to actinic radiation of the second wavelength.

The present invention provides for a media for holographic recording that exhibits a controlled threshold for a recording event. Consequently, multiple recordings (e.g., multiplexed holograms) can be made in a given volume of the polymerizable media without loss of dynamic range due to depletion of photoreactive media components or undesirable light absorption on the sensitizer dye molecules.

The polymerizable media of the present invention and the disclosed inventive methods provide for substantial increase in the storage density as illustrated in FIG. 5.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a schematic diagram showing an exemplary optical architecture for recording Fourier transform volume holograms.

FIG. 2 is a schematic diagram showing a portion the holographic recording media at the area of impact of the object and reference beams.

FIG. 3(a) is a schematic representation of one embodiment of the optical geometry of reference beam and the object beam.

FIG. 3(b) illustrates a detail of FIG. 3(a) at the area of impact of the reference and object beams onto the HRM.

FIG. 4 is a schematic representation a selected storage location in a holographic recording medium (HRM) in cross section view being illuminating with actinic radiation at a first wavelength 1′ that activates the storage location in the HRM for recording holograms.

FIG. 5 is a plot the storage density in bits/μm² as a function of thickness of the recording material in μm.

FIG. 6 is a plot showing diffraction efficiency, η, of multiplexed holograms as a function of recording exposure energy E.

FIG. 7 is a plot of the results of a differential scanning calorimetry (heat flow vs. temperature), indicative of a photo-induced polymerization, of a formulation comprising one of the embodiments of the present invention prior to an activating event.

FIG. 8 is a plot of the results of a differential scanning calorimetry (heat flow vs. temperature), indicative of a photo-induced polymerization, of a formulation comprising one of the embodiments of the present invention, during an activating event.

FIG. 9 is a plot of the results of a differential scanning calorimetry (heat flow vs. temperature), indicative of a photo-induced polymerization, of a formulation comprising one of the embodiments of the present invention, after an activating event.

FIG. 10 is a plot of the results of a differential scanning calorimetry (heat flow vs. temperature), indicative of a photo-induced polymerization, of a TYPE D CROP holographic recording formulation (HRM) comprising one of the embodiments of the present invention, for exposure of the HRM at the activation wavelength before and during an activating event (i.e. the switch compound is in the “off” or inactive state).

FIG. 11 a plot of the results of a differential scanning calorimetry (heat flow vs. temperature), indicative of a photo-induced polymerization, of a TYPE D CROP holographic recording formulation (HRM) comprising one of the embodiments of the present invention, for exposure of the HRM at the recording wavelength after an activating event (i.e. the switch compound is in the “on” or active state).

### DETAILED DESCRIPTION OF THE INVENTION

### Glossary

As used herein, the term “actinic radiation” refers to any electromagnetic radiation capable of initiating photochemical reactions. It includes microwave, IR, VIS and UV wavebands.

As used herein, an “alkyl group”, alone or as a part of a larger moiety (alkoxy, alkylammonium, and the like) is preferably a straight chained or branched saturated aliphatic group with 1 to about 12 carbon atoms, e.g., methyl, ethyl, n-propyl, iso-propyl, n-butyl, sec-butyl, tert-butyl, pentyl, hexyl, heptyl or octyl, or a saturated cycloaliphatic group with 3 to about 12 carbon atoms.

The term “cycloalkyl”, as used herein, means saturated cyclic hydrocarbons, i.e. compounds where all ring atoms are carbons. Examples of cycloalkyl include, but are not limited to, cyclopropyl, cyclobutyl, cyclopentyl, cyclohexyl, and cycloheptyl.

The term “haloalkyl”, as used herein, includes an alkyl substituted with one or more F, Cl, Br, or I, wherein alkyl is defined above.

The terms “alkoxy”, as used herein, means an “alkyl-O—” group, wherein alkyl is defined above. Examples of alkoxy group include methoxy or ethoxy groups.

As used herein, an “alkenyl group”, alone or as a part of a larger moiety (e.g., cycloalkene oxide), is preferably a straight chained or branched aliphatic group having one or more double bonds with 2 to about 12 carbon atoms, e.g., ethenyl, 1-propenyl, 1-butenyl, 2-butenyl, 2-methyl-1-propenyl, pentenyl, hexenyl, heptenyl or octenyl, or a cycloaliphatic group having one or more double bonds with 3 to about 12 carbon atoms.

As used herein, an alkynyl group, alone or as a part of a larger moiety, is preferably a straight chained or branched aliphatic group having one or more triple bonds with 2 to about 12 carbon atoms, e.g., ethynyl, 1-propynyl, 1-butynyl, 3-methyl-1-butynyl, 3,3-dimethyl-1-butynyl, pentynyl, hexynyl, heptynyl or octynyl, or a cycloaliphatic group having one or more triple bonds with 3 to about 12 carbon atoms.

As used herein, an “aryl”, alone or as a part of a larger moiety (e.g., diarylammonium) is a carbocyclic aromatic group, preferably comprising 6-22 carbon atoms. Suitable aryl groups for the present invention are those which 1) do not react directly with light in the absence of an initiator to initiate or induce polymerization of any type; and 2) do not interfere with polymerization. Examples include, but are not limited to, carbocyclic groups such as phenyl, naphthyl, biphenyl and phenanthryl.

The term “heteroaryl”, as used herein, alone or as a part of a larger group, refers to aromatic groups containing one or more heteroatoms (O, S, or N). A heteroaryl group can be monocyclic or polycyclic, e.g. a monocyclic heteroaryl ring fused to one or more carbocyclic aromatic groups or other monocyclic heteroaryl groups. The heteroaryl groups of this invention can also include ring systems substituted with one or more oxo moieties. Examples of heteroaryl groups include, but are not limited to, pyridinyl, pyridazinyl, imidazolyl, pyrimidinyl, pyrazolyl, triazolyl, pyrazinyl, quinolyl, isoquinolyl, tetrazolyl, furyl, thienyl, isoxazolyl, thiazolyl, oxazolyl, isothiazolyl, pyrrolyl, quinolinyl, isoquinolinyl, indolyl, benzimidazolyl, benzofuranyl, cinnolinyl, indazolyl, indolizinyl, phthalazinyl, pyridazinyl, triazinyl, isoindolyl, purinyl, oxadiazolyl, thiazolyl, thiadiazolyl, furazanyl, benzofurazanyl, benzothiophenyl, benzotriazolyl, benzothiazolyl, benzoxazolyl, quinazolinyl, quinoxalinyl, naphthyridinyl, dihydroquinolyl, tetrahydroquinolyl, dihydroisoquinolyl, tetrahydroisoquinolyl, benzofuryl, furopyridinyl, pyrolopyrimidinyl, and azaindolyl.

The foregoing heteroaryl groups may be C-attached or N-attached (where such is possible). For instance, a group derived from pyrrole may be pyrrol-1-yl (N-attached) or pyrrol-3-yl (C-attached).

Suitable substituents on alkyl, alkoxy, alkenyl, alkynyl, aryl, and heteroaryl groups are those which 1) do not react directly with light in the absence of an initiator to initiate or induce polymerization of any type and 2) do not interfere with polymerization. Examples of suitable substituents include, but are not limited to C1-C12 alkyl, C6-C14 aryl, —OH, halogen (—Br, —Cl, —I and —F), —O(R′), —O—CO—(R′), —COOH, —N(R′)₂, —COO(R′), —S(R′) and —Si(R′₃). Each R′ is —H or independently a substituted or unsubstituted aliphatic group or a substituted or unsubstituted aryl group. In one embodiment, R′ is an unsubstituted alkyl group or an unsubstituted aryl group. Preferably, R′ is a C1-C12 alkyl, C1-C12 halogenated alkyl, C3-C10 cycloalkyl; more preferably, R′ is methyl, ethyl, 2-ethylhexyl, cyclohexyl, benzyl or a phenyl group. In another embodiment, R′ is a phenyl substituted with one or more substituent groups such as C1-C12 alkyl, C1-C12 halogenated alkyl, C3-C10 cycloalkyl, halogen, phenyl or benzyl, or C1-C12 alkoxy, optionally substituted with C1-C12 alkyl or C1-C6 haloalkyl or C3-C10 cycloalkyl. More preferably, the substituents on phenyl are methyl, ethyl, 2-ethylhexyl, C1-C12 fluorinated or perfluorinated alkyl, cyclohexyl, benzyl, phenyl, 2-ethylhexyloxy, —OCH₃, chloro, or trifluoromethyl. In some embodiments, alkyl, alkoxy, alkenyl, alkynyl, aryl, and heteroaryl groups can optionally be substituted with one or more halogen, hydroxyl, C1-C12 alkyl, C2-C12 alkenyl or C2-C12 alkynyl group, C1-C12 alkoxy, or C1-C12 haloalkyl.

Further examples of suitable substituents for a substitutable carbon atom in alkyl, alkoxy, alkenyl, alkynyl, aryl, and heteroaryl groups include but are not limited to —OH, halogen (—F, —Cl, —Br, and —I), —R, —OR, —CH₂R, —CH₂OR, —CH₂CH₂OR. Each R is independently an alkyl group. In addition, alkyl, alkenyl, alkynyl, cycloalkyl, alkylene, a heterocyclyl, and any saturated portion of alkenyl, cycloalkenyl, alkynyl, arylalkyl, and heteroaralkyl groups, may also be substituted with ═O, ═S, ═N—R.

In some embodiments, a C6-C14 aryl selected from the group consisting of phenyl, indenyl, naphthyl, azulenyl, heptalenyl, biphenyl, indacenyl, acenaphthylenyl, fluorenyl, phenalenyl, phenanthrenyl, anthracenyl, cyclopentacyclooctenyl or benzocyclooctenyl.

In other embodiments, a 5-14-membered heteroaryl group selected from the group consisting of pyridyl, 1-oxo-pyridyl, furanyl, benzo[1,3]dioxolyl, benzo[1,4]dioxinyl, thienyl, pyrrolyl, oxazolyl, imidazolyl, thiazolyl, a isoxazolyl, quinolinyl, pyrazolyl, isothiazolyl, pyridazinyl, pyrimidinyl, pyrazinyl, a triazinyl, triazolyl, thiadiazolyl, isoquinolinyl, indazolyl, benzoxazolyl, benzofuryl, indolizinyl, imidazopyridyl, tetrazolyl, benzimidazolyl, benzothiazolyl, benzothiadiazolyl, benzoxadiazolyl, indolyl, tetrahydroindolyl, azaindolyl, imidazopyridyl, quinazolinyl, purinyl, pyrrolo[2,3]pyrimidinyl, pyrazolo[3,4]pyrimidinyl, imidazo[1,2-a]pyridyl, and benzothienyl.

In some embodiments, a C6-C14 aryl selected from the group consisting of phenyl, naphthalene, anthracene, 1H-phenalene, tetracene, and pentacene. Alternatively, a C6-C14 aryl selected from the group consisting of indenyl, azulenyl, heptalenyl, biphenyl, indacenyl, acenaphthylenyl, fluorenyl, phenalenyl, phenanthrenyl, cyclopentacyclooctenyl or benzocyclooctenyl. Preferably, a C6-C14 aryl selected from the group consisting of phenyl, naphthalene, anthracene, tetracene, and pentacene.

In some embodiments, a 5-14-membered heteroaryl group selected from the group consisting of pyridyl, furanyl, thienyl, pyrrolyl, imidazolyl, quinolinyl, pyrazolyl, indolyl, purinyl, and benzothienyl. Alternatively, a 5-14-membered heteroaryl group selected from the group consisting of 1-oxo-pyridyl, benzo[1,3]dioxolyl, benzo[1,4]dioxinyl, isoxazolyl, isothiazolyl, isoquinolinyl, benzofuryl, imidazopyridyl, pyrrolo[2,3]pyrimidinyl, pyrazolo[3,4]pyrimidinyl, and imidazo[1,2-a]pyridyl. Preferably, a 5-14-membered heteroaryl group selected from the group consisting of pyridyl, furanyl, thienyl, pyrrolyl, imidazolyl, pyrazolyl, indolyl, and benzothienyl.

In some embodiments, any of the above C6-C14 aryl and/or 5-14-membered heteroaryl are optionally substituted. The substituents are selected from one or more of C1-C12 alkyl, C6-C14 aryl, —OH, halogen, —O(R′), —O—CO—(R′), —COOH, —N(R′)₂, —COO(R′), —S(R′) and —Si(R′₃). Preferably, the substituents are selected from one or more of C1-C12 alkyl, —OH, halogen (preferably, —F), —O(R′), —O—CO—(R′), —N(R′)₂, —COO(R′), and —Si(R′₃). More preferably, the substituents are selected from one or more of C1-C12 alkyl, —OH, —F, —O(C1-C12 alkyl), amine, —N(R′)₂, and —Si(R′₃).

R′ can be any of the above C6-C14 aryl or 5-1-14-membered heteroaryl groups, or a C1-C12 alkyl, C1-C12 halogenated alkyl, C3-C10 cycloalkyl. Preferably, R′ is a C1-C12 alkyl, C1-C12 halogenated alkyl, C3-C10 cycloalkyl; more preferably, R′ is —H, methyl, ethyl, 2-ethylhexyl, cyclohexyl, benzyl or a phenyl group.

### Polymerizable Media

As used herein, a “binder” refers to a compound or composition used in the polymerizable media which is chosen such that it does not inhibit polymerization of the monomers used, such that it is miscible with the monomers used as well as the polymerized or copolymerized structure, and such that its refractive index is significantly different from that of the polymerized monomer or oligomer (e.g., the refractive index of the binder differs from the refractive index of the polymerized monomer by at least 0.04 and preferably at least 0.09). Preferably, a binder is inert to the polymerization processes of the one or more monomer(s) defined herein and, more preferably, is diffusible. Examples of binders for use in holographic recording media are polysiloxanes, due in part to availability of a wide variety of polysiloxanes and the well documented properties of these oligomers and polymers. The physical, optical, and chemical properties of the polysiloxane binder can all be adjusted for optimum performance in the recording medium inclusive of, for example, dynamic range, recording sensitivity, image fidelity, level of light scattering, and data lifetime. The efficiency of holograms produced by the present process in the present medium is markedly dependent upon the particular binder employed. Commonly used binders include poly(methyl phenyl siloxanes) and oligomers thereof, 1,3,5-trimethyl-1,1,3,5,5-pentaphenyltrisiloxane and other pentaphenyltrimethyl siloxanes. Examples are sold by Dow Corning Corporation under the trade name Dow Corning 710 and Dow Corning 705 and have been found to give efficient holograms.

In one embodiment, the polymerizable media of the present invention further includes an IR or near IR (NIR) dye that absorbs IR or NIR radiation, thereby forming heat that is transferred to the compound. Examples of suitable IR dyes are 2-[2-[2-(4-Methylbenzeneoxy)-3-[2-(1,3-dihydro-1,1,3-trimethyl-2H-benz[e]-indol-2-ylidene)ethylidene]-1-cyclohexen-1-yl]-ethenyl]-1,1,3-trimethyl-1H-benz[e]indolium 4-methylbenzenesulfonate, 2-[2-[2-Chloro-3-[(1,3-dihydro-3,3-dimethyl-1-propyl-2H-indol-2-ylidene)-ethylidene]-1-cyclohexen-1-yl]-ethenyl]-3,3-dimethyl-1-propyl-1H-indolium perchlorate, and 2-[2-[2-chloro-3-[(1,3-dihydro-1,3,3-trimethyl-2H-indol-2-ylidene)-ethylidene]-1-cyclohexen-1-yl]ethenyl]-1,3,3-trimethylindolium iodide.

In one embodiment, the polymerizable media comprises a compound that is an aryl endoperoxide, which may be optionally substituted. As used herein, an “endoperoxide” refers to any heterocycle containing a peroxide —O—O— residue in the ring. The peroxide moiety can be attached to any chemically feasible two atoms of an aryl molecule. Preferably, the aryl endoperoxide comprises a substituted or unsubstituted naphthyl endoperoxide, substituted or unsubstituted anthracenyl endoperoxide, substituted or unsubstituted anthracenyl endoperoxide, substituted or unsubstituted naphthacenyl endoperoxide, substituted or unsubstituted naphthacenyl endoperoxide, substituted or unsubstituted pentacenyl endoperoxide, or substituted or unsubstituted pentacenyl endoperoxide. Preferred aryl groups and suitable substituents are as described above for an aryl group. More preferably, the compound is a 9,10-diphenylanthracene-endoperoxide.

In one embodiments, the compound is a compound of the structural formula

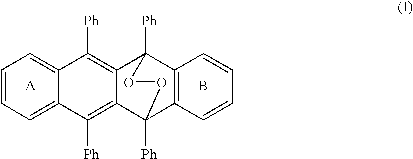

and the sensitizer is a compound having the following structural formula

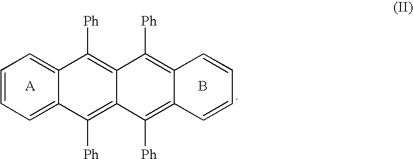

In the formulas above, rings A and B are each independently optionally substituted with one or more group selected from:

—Si(R₅)₃;

C1-C12 alkyl group, optionally substituted with —Si(R₅)₃, a C1-C12 alkoxy, a halogen, an amine, or C1-C12 alkylamine;

C1-C12 alkenyl group, optionally substituted with —Si(R₅)₃, a C1-C12 alkoxy, a halogen, an amine, or C1-C12 alkylamine;

C6-C14 aryl group, optionally substituted with —Si(R₅)₃, a C1-C12 alkoxy, a halogen, an amine, or C1-C12 alkylamine;

a 5-14-membered heteroaryl group, optionally substituted with —Si(R₅)₃, a C1-C12 alkoxy, a halogen, an amine, or C1-C12 alkylamine, and

wherein each R₅ is independently a C1-C12 alkyl, a C6-C14 aryl, or a 5-14-membered heteroaryl group.

Preferably, rings A and B are each independently optionally substituted with one or more group selected from —Si(R₅)₃, C1-C12 alkyl group, a C1-C12 alkenyl group, a C6-C14 aryl group or a 5-14-membered heteroaryl group. Preferred alkyl, alkenyl, aryl and heteroaryl groups and suitable substituents are as described above for the corresponding groups.

In one embodiment, rings A and B are each unsubstituted.

In one embodiment, the polymerizable media of the present invention comprises a compound that undergoes electrocyclic cyclization or retrocyclization upon exposure to actinic radiation of the first wavelength to form the sensitizer which absorbs actinic radiation of the second wavelength. An example of such a reaction is a retro-Diel-Alders reaction.

In one embodiment, the compound is represented by the structural formula

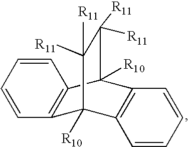

and the sensitizer is represented by the following structural formula

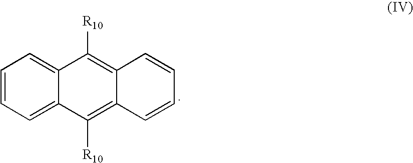

In the structural formulas above, R10, for each occurrence, is independently —H, or an optionally substituted C1-C12 alkyl, an optionally substituted C2-C12 alkenyl, an optionally substituted C2-C12 alkynyl, an optionally substituted C3-C12 cycloalkyl, an optionally substituted C3-C12 cycloalkenyl, an optionally substituted C6-C14 aryl, an optionally substituted 5-14-membered heteroaryl or an optionally substituted —Si(R₆)₃, wherein each R₆ is independently a C1-C12 alkyl, a C6-C14 aryl, or a 5-14-membered heteroaryl group; and R11, for each occurrence, is independently —H or a C1-C12 alkyl; Preferred alkyl, alkenyl, aryl and heteroaryl groups and suitable substituents are as described above for the corresponding groups.

In one embodiment, for each occurrence, the groups represented by R₁₀ and R11 are each optionally substituted by —Si(R₅)₃; C1-C12 alkyl group, preferably, C1-C12 alkyl, optionally substituted with —Si(R₅)₃, a C1-C12 alkoxy, a halogen, an amine, or C1-C12 alkylamine (preferably C1-C6 alkylamine); C1-C12 alkenyl group (preferably C1-C6 alkenyl), optionally substituted with —Si(R₅)₃, a C1-C12 alkoxy, a halogen, an amine, or C1-C12 alkylamine; C6-C14 aryl group, optionally substituted with —Si(R₅)₃, a C1-C12 alkoxy, a halogen, an amine, or C1-C12 alkylamine; and a 6-14-membered heteroaryl group, optionally substituted with —Si(R₅)₃, a C1-C12 alkoxy, a halogen, an amine, or C1-C12 alkylamine, and wherein each R₅ is independently a C1-C12 alkyl, a C6-C14 aryl, or a 6-14-membered heteroaryl group, each optionally substituted by one or more groups selected from C1-C12 alkoxy, halogen, amine or C1-C12 alkylamine. Preferred alkyl, alkenyl, aryl and heteroaryl groups and suitable substituents are as described above for the corresponding groups. In one embodiment, a C1-C12 alkyl, alone or as a part of any other groups, is a C1-C6 alkyl.

Preferably, the optional substituents on the group R10 are each, independently, selected from C1-C12 alkyl, C1-C12 alkoxy, amine, C1-C4 alkylamine, or a halogen. In one embodiment, each R11 is, independently, a methyl or an ethyl. Preferably, each R11 is a methyl.

In one embodiment, the polymerizable media of the present invention comprises a compound that undergoes a molecular rearrangement reaction upon exposure to actinic radiation of the first wavelength to form the sensitizer which absorbs actinic radiation of the second wavelength. An example of such a rearrangement is a 6π electrocyclic cyclization upon exposure to actinic radiation of the first wavelength.

In some embodiments, the compound that undergoes a molecular rearrangement is selected from the group consisting of spiropyrans, spiro-oxazines, fulgides (dialkylidenesuccinic anhydrides), triarylmethanes, naphthopyrans, diarylethenes and diheteroarylethenes. Preferably, the compound is a diarylethene or a diheteroarylethene, and wherein the aryl or heteroaryl moiety is selected from the group consisting of a substituted or unsubstituted phenyl, a substituted or unsubstituted naphthyl, a substituted or unsubstituted thiophene, a substituted or unsubstituted benzathiophene, a substituted or unsubstituted pyrrole, and a substituted or unsubstituted indole. In some embodiments, the ethene moiety of the diarylethene and diheteroarylethene is optionally substituted and/or is a part of an optionally substituted cycloalkene, an optionally substituted anhydride, or optionally substituted maleimide. Where the ethene moiety is an optionally substituted cycloalkene, the cycloalkene moiety is a C4-C6, optionally perfluorinated, cycloalkene. Preferred alkyl, alkenyl, aryl and heteroaryl groups and suitable substituents are as described above for the corresponding groups.

In some embodiments, the compound that undergoes a molecular rearrangement is represented by the following structural formula:

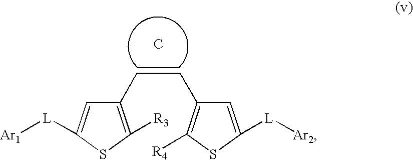

and the sensitizer is represented by the following structural formula

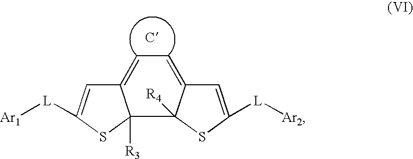

In the structural formulas above, ring C is an optionally fluorinated or perfluorinated C3-C7 cycloalkenyl and ring C′ is an optionally fluorinated or perfluorinated C3-C7 cycloalkane; each L is independently an inert linker; Ar₁ is an optionally substituted C6-C22 aryl or an optionally 5-14-membered heteroaryl; Ar₂ is independently an Ar₁, optionally substituted with an electron withdrawing group, or is an electron withdrawing group; R₃ and R₄ are each independently selected form a C1-C12 alkyl group, a C1-C12 alkenyl group, or a C1-C12 alkoxy group. Preferred alkyl, alkenyl, aryl and heteroaryl groups and suitable substituents are as described above for the corresponding groups.

As used herein, the term “inert linker” refers to a moiety which: 1) does not react under conditions which induce or initiate polymerization; 2) does not interfere with polymerization; 3) and does not interfere with chemical segregation of the binder from a polymer formed during polymerization. Examples of linkers include a C1-C12 alkyl, C1-C12 alkylether, and siloxanes.

In one embodiment, the compound is represented by the following structural formula

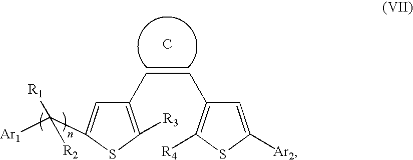

and the sensitizer is represented by the following structural formula

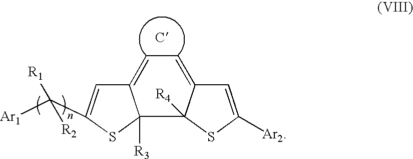

In the above structural formulas, n is 0, 1 or 2; and R₁, R₂, are each independently selected form a C1-C12 alkyl group, a C1-C12 alkenyl group, or a C1-C12 alkoxy group.

Preferably, the electron withdrawing group is selected from —NO2, —CF3, C1-C4 trialkylammonium, —C(O)OR′, —CN, —SO3R′, a halogen, wherein R′ is —H or a C1-C12 alkyl. In some embodiments, ring C is a perfluorocyclopentene and ring C′ is a perfluorocyclopentane.

In some embodiments, Ar₁ for each occasion is independently optionally substituted with a group represented by R^{y}, wherein R^{y} is an optionally substituted C1-C12 alkyl, an optionally substituted C2-C12 alkenyl, an optionally substituted C2-C12 alkynyl, an optionally substituted C3-C12 cycloalkyl, an optionally substituted C3-C12 cycloalkenyl, an optionally substituted C6-C14 aryl, or an optionally substituted 5-14-membered heteroaryl or is an electron-donating group selected from C1-C12 alkoxy, C1-C4 dialkylamine, or a C6-C14 diarylamine. Preferably, the optional substituent on the group represented by R^{y}, for each occurrence, is independently selected from —Si(R₅)₃; C1-C12 alkyl group, optionally substituted with —Si(R₅)₃, a C1-C12 alkoxy, a halogen, an amine, or C1-C6 alkylamine; C1-C12 alkenyl group, optionally substituted with —Si(R₅)₃, a C1-C12 alkoxy, a halogen, an amine, or C1-C6 alkylamine; C6-C14 aryl group, optionally substituted with —Si(R₅)₃, a C1-C12 alkoxy, a halogen, an amine, or C1-C6 alkylamine; a 6-14-membered heteroaryl group, optionally substituted with —Si(R₅)₃, a C1-C12 alkoxy, a halogen, an amine, or C1-C6 alkylamine, and wherein each R₅ is independently a C1-C12 alkyl, a C6-C14 aryl, or a 6-14-membered heteroaryl group. Preferred alkyl, alkenyl, aryl and heteroaryl groups and suitable substituents are as described above for the corresponding groups.

In one embodiment, the polymerizable media of the present invention comprises a compound that undergoes oxidation upon exposure to actinic radiation of the first wavelength to form the sensitizer which absorbs actinic radiation of the second wavelength. Examples of such compounds are a bis((trimethylsilyl)ethynyl)pentacene or bis(ethynl(phenyl))naphthacene.

Preferably, the oxidation reaction is radically initiated oxidation reaction. In some embodiments, the compound that undergoes the oxidation reaction is an optionally substituted naphthacene, an optionally substituted pentacene, an optionally substituted phenanthrene, an optionally substituted pyrene, or an optionally substituted anthracene.

In some embodiments, the compound that undergoes the oxidation reaction the compound is represented by the following structural formula

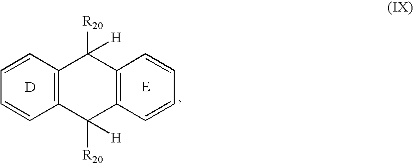

and the sensitizer is represented by the following structural formula

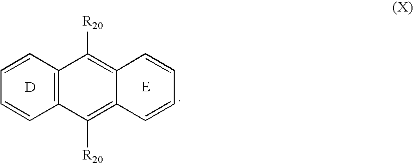

In the structural formulas above, R20, for each occurrence, is independently an optionally substituted C1-C12 alkyl, an optionally substituted C2-C12 alkenyl, an optionally substituted C2-C12 alkynyl, an optionally substituted C3-C12 cycloalkyl, an optionally substituted C3-C12 cycloalkenyl, an optionally substituted C6-C14 aryl, an optionally substituted 5-14-membered heteroaryl or an optionally substituted —Si(R₈)₃, wherein each R₈ is independently a C1-C12 alkyl, a C6-C14 aryl, or a 5-14-membered heteroaryl group; and rings D and E are each independently optionally substituted with one or more group selected from —Si(R₈)₃; C1-C12 alkyl group, optionally substituted with —Si(R₈)₃, a C1-C12 alkoxy, a halogen, an amine, or C1-C6 alkylamine; C1-C12 alkenyl group, optionally substituted with —Si(R₈)₃, a C1-C12 alkoxy, a halogen, an amine, or C1-C6 alkylamine; C6-C14 aryl group, optionally substituted with —Si(R₈)₃, a C1-C12 alkoxy, a halogen, an amine, or C1-C6 alkylamine; a 5-14-membered heteroaryl group, optionally substituted with —Si(R₈)₃, a C1-C12 alkoxy, a halogen, an amine, or C1-C6 alkylamine, and wherein each R₈ is independently a C1-C12 alkyl, a C6-C14 aryl, or a 5-14-membered heteroaryl group. Preferred alkyl, alkenyl, aryl and heteroaryl groups and suitable substituents are as described above for the corresponding groups.

Preferably, R20 for each occurrence, is independently a C1-C12 alkyl, such as methyl or ethyl. Rings E and D are each, preferably, unsubstituted.

In one embodiment, the polymerizable media of the present invention comprises a compound that undergoes a conformational rearrangement upon exposure to actinic radiation of the first wavelength. For example, the compound undergoes a cis/trans izomerization of a carbon-carbon double bond upon exposure to actinic radiation of the first wavelength to form the sensitizer which absorbs actinic radiation of the second wavelength.

In one embodiment, such a compound is an optionally substituted diarylethene. For example, the compound is represented by the structural formula

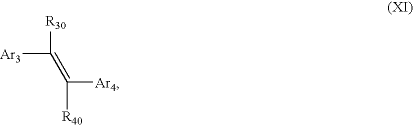

and the sensitizer is represented by the following structural formula

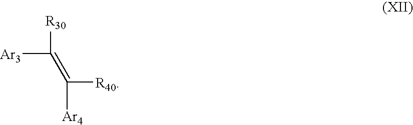

In the structural formulas above, Ar₃ and Ar₄ are each independently an optionally substituted C6-C14 aryl or an optionally 5-14-membered heteroaryl; R₃₀ and R₄₀ are independently selected from hydrogen, optionally substituted C1-C12 alkyl group, or a 5-14 membered heteroaryl.

Preferably, in the embodiments in which R₃₀ and R₄₀ are each independently an optionally 5-14-membered heteroaryl, the heteroaryl group is selected from optionally substituted thiophenyl group, optionally substituted furanyl group, optionally substituted pyrrolyl group, and optionally substituted pyridinyl group. Preferred alkyl, alkenyl, aryl and heteroaryl groups and suitable substituents are as described above for the corresponding groups.

In one embodiment, each group represented by Ar₃, Ar₄, R₃₀ and R₄₀ are independently, for each occurrence, optionally substituted with one or more group selected from —Si(R₅)₃; C1-C12 alkyl group, optionally substituted with —Si(R₅)₃, a C1-C12 alkoxy, a halogen, an amine, or C1-C6 alkylamine; C1-C12 alkenyl group, optionally substituted with —Si(R₅)₃, a C1-C12 alkoxy, a halogen, an amine, or C1-C6 alkylamine; C6-C14 aryl group, optionally substituted with —Si(R₅)₃, a C1-C12 alkoxy, a halogen, an amine, or C1-C6 alkylamine; a 5-14-membered heteroaryl group, optionally substituted with —Si(R₅)₃, a C1-C12 alkoxy, a halogen, an amine, or C1-C6 alkylamine, and wherein each R₅ is independently a C1-C12 alkyl, a C6-C14 aryl, or a 5-14-membered heteroaryl group. Preferred alkyl, alkenyl, aryl and heteroaryl groups and suitable substituents are as described above for the corresponding groups.

Preferably, Ar₃ and Ar₄ are each independently an optionally substituted with one or more groups represented by R^{a} and one or more group represented by R^{b}. Each R^{a} is independently selected from optionally substituted (C0-C3 alkyl)ethenyl group, optionally substituted (C0-C3 alkyl)ethynyl group, optionally substituted phenyl group, optionally substituted thiophenyl group, optionally substituted furanyl group, optionally substituted pyrrolyl group, and optionally substituted pyridinyl group; and each R^{b} is independently selected from —H, a halogen, or a C1-C12 alkyl group. The optional substituents on the group represented by R^{a} is optionally are selected from one or more of —Si(R₅)₃; C1-C12 alkyl group, optionally substituted with —Si(R₅)₃, a C1-C12 alkoxy, a halogen, an amine, or C1-C6 alkylamine; C1-C12 alkenyl group, optionally substituted with —Si(R₅)₃, a C1-C12 alkoxy, a halogen, an amine, or C1-C6 alkylamine; C6-C14 aryl group, optionally substituted with —Si(R₅)₃, a C1-C12 alkoxy, a halogen, an amine, or C1-C6 alkylamine; a 6-14-membered heteroaryl group, optionally substituted with —Si(R₅)₃, a C1-C12 alkoxy, a halogen, an amine, or C1-C6 alkylamine, and wherein each R₅ is independently a C1-C12 alkyl, a C6-C14 aryl, or a 5-14-membered heteroaryl group. Preferred alkyl, alkenyl, aryl and heteroaryl groups and suitable substituents are as described above for the corresponding groups.

In one embodiment of the present invention, the formed sensitizer is a linear absorbing dye. Alternatively, the formed sensitizer is a non-linear-absorbing dye. In one embodiment, the formed sensitizer is a 2-photon absorbing dye.

As stated above, the polymerizable media of the present invention comprises an initiator. The initiator can initiate any type of a polymerization reaction. In one embodiment, the initiator is a photoacid generator (PAG), and wherein the PAG produces acid in combination with the sensitizer. Preferably, the PAG is a sulfonium, iodonium, diazonium, or phosphonium salt.

In some embodiments, at least one monomer or oligomer included into the polymerizable media of the present invention undergoes cationic polymerization. Preferably, the monomer or oligomer which is capable of undergoing polymerization contains one or more epoxide, oxetane, cyclic ether, 1-alkenyl ether, unsaturated hydrocarbon, lactone, cyclic ester, lactam, cyclic carbonate, cyclic acetal, aldehyde, cyclic sulfide, cyclosiloxane, cyclotriphosphazene, or polyol functional groups, or a combination thereof. More preferably, the epoxide monomer is a siloxane, siloxysilane comprising two or more cyclohexene oxide groups, or a polyfunctional siloxane comprising three or more cyclohexene oxide groups. For example, the monomer is an epoxide monomer that comprises one or more cyclohexene oxide groups. Suitable monomers are described, for example, in Further description of suitable siloxane monomers can be found in aforementioned U.S. Pat. Nos. 6,784,300 and 7,070,886 and PCT Publication WO 02/19040, the entire teachings of which are incorporated herein by reference.

Alternatively, the polymerizable media of the present invention comprises an initiator that is a free radical generator, and wherein the free radical generator produces free radicals in combination with the sensitizer. In such an embodiment, the polymerizable media comprises at least one monomer or oligomer undergoes free radical polymerization. Preferably, the produced free radicals initiates free radical polymerization reactions. An example of a sensitizer that can be formed from a compound in such a polymerizable media is diphenylanthracene.

In some embodiments, the polymerizable media of the present invention further includes colloidal particles suspended in the HRM, said particles generating heat when exposed to actinic radiation. In certain embodiments, the compound, which absorbs actinic radiation of a first wavelength, is adsorbed to said colloidal particles. The colloidal particles can be metal particles or particles of carbon black.

### Methods of Polymerization and Recording Holograms

As stated above, in one embodiment, the present invention is a method of polymerizing a polymerizable media. The method comprises steps (a) exposing a first location in the polymerizable media to actinic radiation of the first wavelength, thereby forming a sensitizer from the compound; and (b) exposing the first location in the polymerizable media to actinic radiation of the second wavelength, thereby initiating polymerization of the at least one monomer or oligomer.

In another embodiment, the present invention is a method of recording a hologram. The method comprises steps (a) exposing a first storage location in the holographic recording media to a beam actinic radiation of the first wavelength, thereby forming a sensitizer from the compound, said sensitizer absorbing actinic radiation of a second wavelength; and (b) directing a reference beam of coherent light of the second wavelength and an object beam of coherent light of the second wavelength at the first storage location, thereby forming an interference pattern at the first storage location between the object beam and the reference beam, initiating polymerization of the at least one monomer or oligomer and thereby recording the interference pattern as a hologram within said first storage location.

A hologram can be a binary data page hologram. For example, the data page hologram is recorded with an object beam that is amplitude modulated or phase modulated.

Alternatively, the hologram can be a micrograting recorded in a portion of a volume of the first storage location in the holographic recording media (HRM). One or more microgratings can be recorded in a portion of the volume of the first storage location by repeating step (b) at the first storage location, thereby recording multiplexed microgratings that overlap at least in part in the said portion of the volume of the first storage location. The multiplexed microgratings can be recorded with two or more different wavelengths or two or more different phases.

In either the method of polymerizing, or the method of recording holograms, steps (a) and (b) can be repeated, and for each repetition of step (a), step (b) is repeated one or more times. Steps (a) and (b) can occur substantially at the same time. Preferably, steps (a) and (b) are performed at a second location in the polymerizable media. The second location can abutting or overlapping the first location. Alternatively, the second location is neither abutting or overlapping the first location.

In some embodiments, the beam of actinic radiation of the first wavelength, the reference beam or the object beam are produced by a source of actinic radiation that is a continuous emitting source or a pulsed source. Examples of the source of actinic radiation include a diode laser, and further, wherein the diode laser optionally comprises an external cavity. In some embodiments, the beam of actinic radiation of the first wavelength, the reference beam, or the object beam is each independently generated by a tunable source.

In some embodiments, the beam of actinic radiation of the first wavelength is a collimated or a substantially collimated beam.

The beam of actinic radiation of the first wavelength, the reference beam or the object beam can each independently have a Gaussian intensity distribution at the first storage location. Alternatively, the beam of actinic radiation of the first wavelength, the reference beam or the object beam can each independently have a truncated Gaussian intensity distribution at the first location in the HRM, wherein the minimum diameter of the truncated Gaussian intensity distribution is less than or equal to the diameter of said beam, d_{1/e}_{²}, measured at the 1/e² intensity point.

In certain embodiments, exposing the first location to actinic radiation of the first wavelength, the reference beam or the object beam exposes a volume element of the HRM having a cross-sectional area that changes as a function of depth through the HRM.

The amount of formed sensitizer can be controlled by the intensity of the actinic radiation of a first wavelength or by the duration of the exposure of the compound to the actinic radiation of a first wavelength.

The actinic radiation of a first wavelength can be used as a source of light for generating a servo signal from the media.

In some embodiments of the present invention, the method of polymerizing the media and the method of recording a hologram can further include a step (c) of reading the recorded hologram after recording the hologram at the first storage location, wherein the reading step confirms the recording of the hologram at the first storage location. Step (c) can further include reading the recorded micrograting hologram after recording the micrograting hologram at the first storage location, wherein the reading step confirms the recording of the micrograting hologram at the first storage location.

In some embodiments of the present invention, the method of polymerizing the media and the method of recording a hologram can further include performing steps (a) and (b) at a second storage location in the holographic recording media before steps (a) and (b) or step (b) are repeated at the first storage location in the holographic recording media for recording multiplexed holograms at the first storage location. Steps (a) and (b) are repeated at the first storage location for recording multiplexed holograms at the first storage location, after performing steps (a) and (b) at the second storage location in the holographic recording media.

It is desirable for a media for holographic recording, where multiple recordings are taking place in a simultaneous or sequential manner, or during interrupted recording sessions, to have a photoactive media that exhibits a true and controlled threshold for a recording event. This is desirable for a number of reasons, for example, to simplify the recording schedule, to improve image fidelity, to improve efficiency of polymerizing monomer or oligomer for recording holograms, to improve the handling quality and possibly improve pre-recorded shelf-life. In this invention a new initiation system that can be activated in-situ in a specific location while the surrounding location(s) are left in an inactive state is contemplated. In such a system it is contemplated that the photo-sensitizer, the dye-like compound that imparts photosensitivity at a desired wavelength, can be activated or switched from a non-reactive state to a reactive state using an external stimuli such as light, heat or a combination of both. Once the dye compound has been switched or activated to the reactive state, the dye compound can be used as an actinic light sensitizer for initiation of a photo-polymerization process, where such processes could be used for micro lithography or hologram recording.

In such a system the media would be prepared and conditioned so as to be nonreactive to a 1^{st} wavelength λ₁, the wavelength of data recording or the desired wavelength for photo-activity. Recording data would follow the steps of (1) activating a region to be recorded by action of light of a second wavelength λ₂, or by the action of heat or a combination of both, (2) followed by data recording at the desired wavelength, λ₁ and (3); subsequently moving to a new recording location, say an abutting region or an overlapping region, where the process could be repeated. In the dye activation process the abutting regions are desirably inactive to the recording wavelength and thus abutting regions are not impacted by recording in neighboring areas. Even the spillover light due to the excess volume of illumination by the recording beams would not cause pre-consumption of dynamic range in these regions.

In such a system it contemplated that the photosensitizer can be switched from a non-reactive state to a reactive state by a molecular reorganization such as exhibited in photochromic compounds. It is further contemplated that the reorganization is a cis-trans isomerization. It is further contemplated that the re-organization is a cycloreversion process initiated by an external stimuli such as light, heat or a combination of both. Following the activation or switching process the dye compound can be used as a actinic light sensitizer for initiation of a photo-polymerization process, where such processes could be hologram recording.

In this invention it is contemplated that an initiator can be introduced into a formulation for photo-polymerization and holographic recording comprising monomers, oligomers, binders and the like, and said initiator can be introduced in a form that makes the media substantially nonreactive to a particular and desirable wavelength of light. It is also contemplated that the initiator can be converted directly or indirectly to a new species either through action of light or heat.

It is further contemplated that the initiator of the present invention is a photochromic compound that can be introduced into a formulation in an inactive state and that said initiator in the inactive state can be converted via a molecular reorganization to an active state by the action of light or heat.

Examples of photochromic compounds include but are not limited to: Spiropyrans, spiro-oxazines, fulgides, triarylmethanes, quinones, naphthopyrans and diarylethenes. Diarylethenes are represented by stilbene, azoarene, diaryleperfluorocycloalkenes (butane, pentene, hexene), diarylmaleic anhydrides and diarylmaleimides and other such compound that undergo a reversible transformation, as indicated in the reaction scheme below, from a colorless to a colored form.

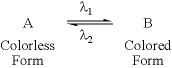

It is additionally contemplated a dye/sensitizer coupled to a photo-chromic compound or switch, where the dye is attached via a linking group. In such a system it is contemplated that the switch moiety is substantially decoupled from the sensitizer dye moiety in the active state but the switch moiety acts as an energy sink and blocks or substantially interferes with the sensitization process in the deactivated state. In such a system it is contemplated that the Dye moiety would be attached to the switch moiety via a linking groups such as an alkyl group. Examples of such a system are compounds of formulas (VII) and (VIII) presented above.

It is further contemplated that after the initiator is converted into the active state that the formulation will be reactive when exposed to actinic radiation of a desirable wavelength and that photo-polymerization can occur.

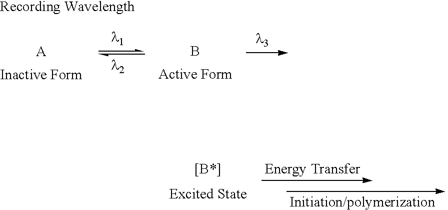

It is further contemplated that the conversion from the inactive state to the active state is a unimolecular process where the inactive form of the initiator undergoes a thermal or photochemical decomposition or fragmentation to give an active form and a byproduct. The byproduct can be inert or reactive:

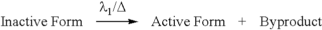

Examples include but are not limited to: Aryl-endoperoxides such as rubrene endoperoxide and 9,10-diphenylanthracene-endoperoxide or 1,1,3 triphenyl-2-indanone.

Similarly, it is contemplated that the initiator or photosensitizer of the present invention in the inactive form is a dye precursor and can be converted to the active form by undergoing a chemical reaction such as a retro-cyclization reaction where the activation can be either heat or light. A general example is given below.

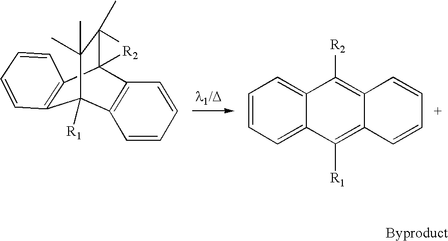

Thermal or light induced retro-cyclization of a Diels-Alder adduct.

It is further contemplated that after the initiator is converted into the active state that the formulation will be reactive when exposed to actinic radiation of a desirable wavelength and that photo-polymerization can occur.

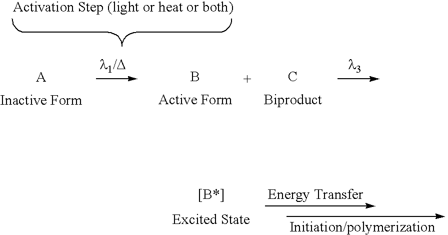

It is further contemplated that the inactive form can be converted to an active form by a chemical reaction such as a radical initiated oxidation, see reaction Scheme 1. Here it is contemplated that the precursor compound undergoes an oxidative chemical change to form the active species by the action of a radical, wherein the radical can be formed by either light or heat.

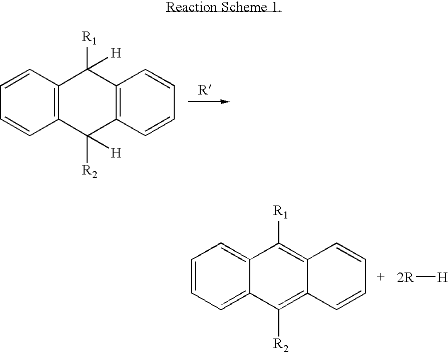

It is contemplated that the initiator of the present invention is a photo-sensitizer that interacts with a photoacid generator, photobase generator or photoradical generator to provide an initiating species when the initiator of the present invention is in the active form.

It is further contemplated that the conversion from the inactive state to the active state is a bi-molecular process where the action of the activating stimuli causes the precursor form to decompose to give the desired sensitizer dye and a byproduct. Said precursor form can be a small molecule or can be attached to a larger molecular frame work such as a polymer or oligomer. Said precursor can be attached to a nanoparticle or a fullerene

It is further contemplated that the conversion from the inactive state to the active state is a multi-molecular process.

It is contemplated that the heat process can be initiated via a direct method such via radiant heating. It is contemplated the heat process can be initiated via an indirect methods by incorporation of an IR of NIR sensitive dye or a colloidal metal particle and use of an IR source or a visible light source, such as laser diode. It is further contemplated that the heat step can be done via secondary process where a laser source such as an IR or near IR laser can be used to heat a location in the storage medium thereby causing a heat activated dye forming reaction. It is also contemplated that the media can be made susceptible to IR or Near IR irradiance by incorporating a IR dye or colloidal metal particles to absorb said IR irradiance. It is also contemplated that the IR dye can be attached to a nano-particle. It is further contemplated that the precursor dye compound can be attached to a nanoparticle and that both the precursor and the IR dye can be attached to the same nanoparticle to facilitate the efficiency of dye activation.

In certain embodiments, a compound that forms a sensitizer undergoes a trans-cis isomerization around a carbon-carbon double bond. For example, a short wavelength chromophore in conjugation with a species that will lengthen the λmax of absorbance, will shorten the λmax of absorbance upon a trans-cis isomerization.

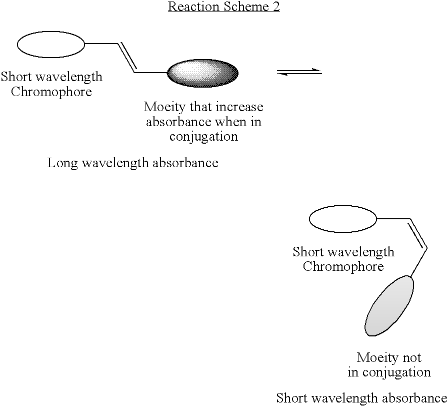

In various embodiments, effective mechanisms for cycling between off and on states (i.e. between a compound that forms a sensitizer and the sensitizer) include thermal activation to a new absorbance species, photochemical activation to a new absorbance species, and bi- or multi-molecular process leading to a new absorbance species via a chemical reaction.

Methods of reducing extinction coefficient or changing concentration of the compounds for photoinitiation can improve uniformity of developed refractive index modulation during recording as a function of depth into the recording material, however, photopolymerization is still initiated at the wavelength(s) used for recording the holograms and the extent of polymerization is directly dependent upon the magnitude of the irradiance, typically in units of mJ/cm², of the exposure used for recording. Consequently, photoinitiation of polymerization reactions occurs wherever light is incident in the volume of the material during recording, such as where the Reference beam and Object beam must overlap for formation of the interference pattern needed to record a hologram as well as where light incident from the Reference and Object beams does not overlap. Further, if the Reference beam is incident at oblique angles with respect to the optical axis of the Object beam, or if the said volume of overlap has varying cross-sectional area as a function of depth through the recording material, both of which can occur during recording of volume holograms and at least one such condition generally occurs for recording of volume holograms, then an excess of the volume at or near a selected storage location(s) is exposed to light that causes photoinitiation and thus occurrence of undesirable polymerization reactions. The effects of the said excess volume being exposed during a recording event is further compounded by the need to achieve as high a multiplexing number as possible for each storage location so as to achieve a high value for areal storage density, and thus a grouping of exposures are made in substantially the same storage location wherein each said exposure initiates polymerization reactions undesirably in the said excess volume.

Further, although areal density of stored information in a storage location can be increased by increasing the numerical aperture (NA) of the imaging optics due to concomitant reduction in the Nyquist aperture, defined as Ny=1.22*2λf/δ, wherein λ is wavelength of recording light, f is focal length of imaging lens, and δ is pitch of the pixels of the encoding device such as a spatial light modulator (SLM), or the Rayleigh length for recording of microgratings, the degree of differentiation for cross-sectional area as a function of depth through the recording material also increases with NA. For example, for Fourier transform holograms the area of the Object beam at the Fourier plane in the recording material is Ny², but, by way of example, if the Fourier plane is at the center of the recording material than the area of the Object beam is larger at or near the top and bottom surfaces of the material.

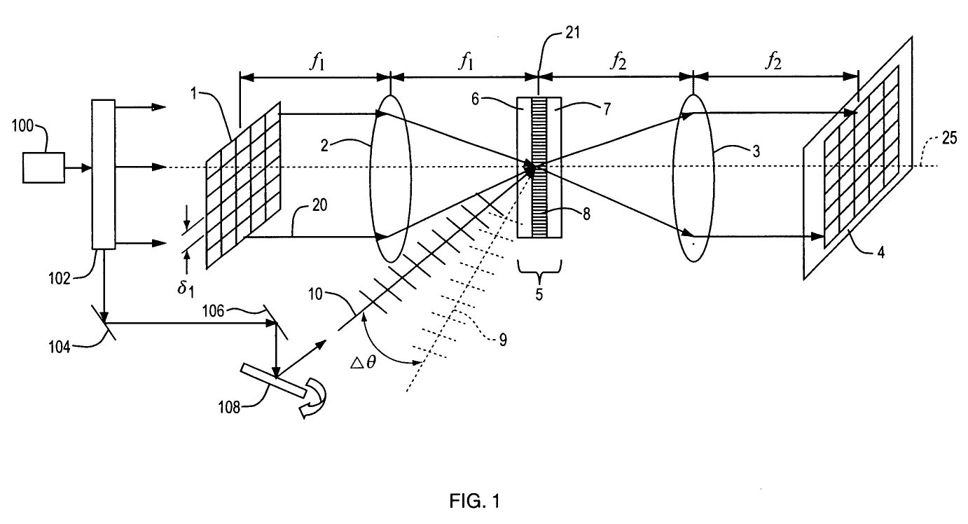

By way of example, a classical optical architecture for recording Fourier transform volume holograms such as of binary data pages is depicted in FIG. 1, wherein the Fourier plane is at location (21) in the recording material and where f₁=f₂ for the lens elements (2) and (3) in a 4f recording/reading geometry having SLM (1) and detector (4). The Reference beam depicted as (10), by way of example, is incident upon the storage location in recording material (8) at an oblique angle with respect to the optical axis (25) of the Object beam (20), and the Reference beam (10) is incremented by an amount Δθₗ for the case of planar-angle multiplexing over an aggregate range of incident angles Δθ, such as up to a largest incident Reference beam angle (9), wherein the magnitude of Δθₗ for the ith recorded hologram in a storage location is related inversely to the thickness of the recording material for a given optical geometry and wavelength.

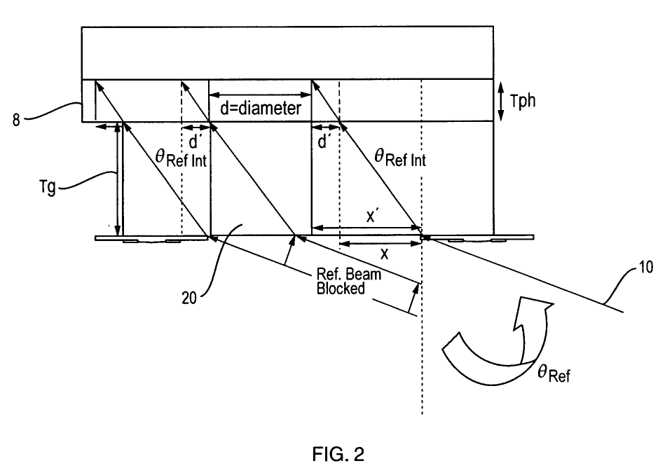

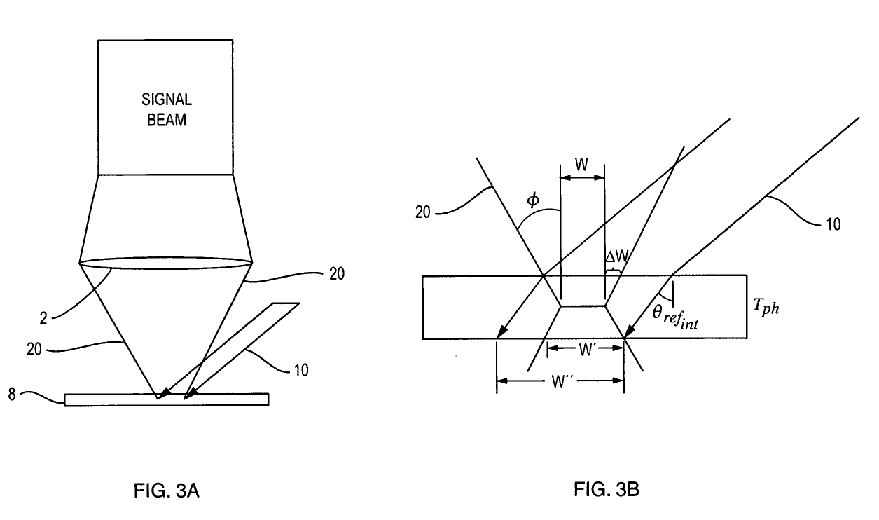

The undesirable use of a portion of the limited number of available chemical reactions for hologram formation for each multiplexing recording event in a selected storage location, due to the said excess volume being exposed, is further exacerbated by the need to increase the thickness of the recording material so as to achieve larger values for areal density. The impact of increasing thickness on the said excess exposed volume is depicted in FIG. 2. Reference beam (10) of FIG. 1 needs to be oversized in its lateral dimension at front face of the substrate of media (5) by an amount x to compensate for it propagating at an oblique angle through thickness T_{g} of the front substrate (e.g. glass) of media (5), and by an amount x′ to further propagate through the thickness (Tₚₕ) of recording material (8) so as to intersect the edge of the cross-section area of the Object beam (20) at the back plane of the recording material (8), wherein d is the lateral dimension of the Object beam (20) and d′ is the corresponding oversize amount at the front and back surfaces of recording material (8) that is needed to provide for overlap of the interaction volume of the Reference beam (10) and Object beam (20) throughout the thickness (Tₚₕ) of the recording material (8). The said oversize amount is an excess lateral dimension that results in an excess volume being undesirably exposed. In FIG. 2 the lateral dimension of the Object beam (20) is depicted as being uniform throughout the thickness of the media (5), for purposes of simplification, whereas for Fourier transform holograms the lateral dimension is often a minimum in the center and is larger at or near the front and back surfaces of media (5), as shown in FIG. 3(a) and FIG. 3(b), so as to maximize storage density. An adjustable blocking of a portion of the Reference beam can optionally be used to reduce the amount of scattered light originating from excess volume in the substrates that may propagate in the forward direction from the substrates of media (5) into recording material (8), wherein the dimension or size of the adjustable portion can be changed as a function of the incident angle of Reference beam (10).

By way of example, for a Reference beam incident on the media at non perpendicular angles (i.e. oblique angles), the size of the excess lateral dimension exposed in the media during recording is proportionally affected by the thickness of the recording material, Tₚₕ, for the range of Reference beam angles used during multiplexed recording up to the maximum angle as shown in Equation (3) as

tan(90−θ_{Ref}_{_{Int}})=Tₚₕ/d′ Eqn. (3)

where θ_{Ref}_{_{Int}} is the maximum internal angle for the Reference beam (10) in recording material (8) such as for a grouping of planar-angle multiplexing recordings in a selected storage location in the material (8).

FIG. 3(a) is a schematic representation of one embodiment of the optical geometry of reference beam 10 and object beam 20, wherein object beam 20 is relayed by optical element 2 to HRM 8 and reference beam 10 is incident onto HRM 8 at oblique angles of incidence.

FIG. 3(b) illustrates a detail of FIG. 3(a) at the area of impact of the beams 10 and 20 onto HRM 8. FIG. 3(b) depicts schematically in cross-sectional view an example case for recording Fourier transform data page holograms with 2-axis multiplexing methods wherein the parameters for purposes of calculation of areal density of recorded holograms are size of the SLM is N_{SLM}=1024 pixels having pitch δ=12 microns, wavelength λ=0.407 μm, average refractive index of the recording material is nₐᵥₑ=1.52, the range of the external angles of the Reference beam is between 35-65 degrees from the perpendicular to the recording material, φ is the maximum internal cone angle of the FT intensity distribution for the Object beam, θ_{Ref}_{_{Int}} is the maximum internal angle for the Reference beam for 2-axis recording methods, the minimum diffraction efficiency for two-axis recording of binary data pages is η_{eff}=1.0e−3 for minimum acceptable signal-to-noise of the reconstructed multiplexed data page holograms for this exemplification, and the cumulative grating strength of the recording material in an isolated storage location is set for a dynamic range of 5 per 200 μm thickness of the recording material for this exemplification and is attainable in thinner materials by use of dual multiplexing methods such as, by of example, combination of planar-angle and out-of-plane angle multiplexing. The maximum internal cone angle of FT intensity distribution for the Object beam, φ, can thus be defined as

φ=sin⁻¹{sin [tan⁻¹(N_{SLM}*δ/2f)]/nₐᵥₑ} Eqn. (4)

and the excess lateral dimension of the Object beam, ΔW, at the top and bottom surfaces of the recording material reduces the areal storage density of recorded holograms due to the lateral dimension of the Object beam, W, being expanded to W′ at the surface as

W′=W+2ΔW Eqn. (5)

The lateral dimension of the recording Reference beam, W″, must therefore be set to

W″=W+2ΔW+Tₚₕ*tan θ_{Ref}_{_{Int}} Eqn. (6)

so as to compensate fully for the oblique angle of incidence of the Reference beam to provide for overlap of the Object and Reference beams in the interaction volume of the selected storage location(s). Consequently, the excess lateral dimension of the exposure area at the storage location increases monotonically with the thickness of the recording material, Tₚₕ, and, further, the dependence of areal storage density of multiplexed recording is diminished from the linear scaling of dynamic range of the recording material with material thickness, Tₚₕ, that could otherwise be exhibited if no excess lateral dimension occurred for the exposure area during recording.

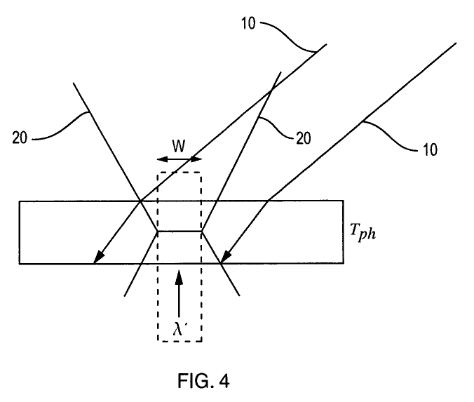

FIG. 4 shows illumination of a selected storage location in a holographic recording medium, in cross section view, by actinic radiation at a first wavelength, λ′ that activates the said medium for the step of recording holograms. The lateral dimension of the exposure with actinic radiation at a first wavelength is shown as the dimension W corresponding to the minimum dimension of the object beam during recording in the volume of the selected storage location. In certain embodiments the said lateral dimension of the exposure with actinic radiation at a first wavelength can be smaller or larger than W. Further, in certain embodiments the lateral dimension can change its size through the thickness of the recording material at the selected storage location, such as due to converging or diverging wavefronts for said illumination, and, further, can have a shape that is not symmetric in the lateral dimensions. The exposure with actinic radiation at a first wavelength can have an intensity distribution that is a Gaussian intensity distribution in the volume of the selected storage location for activating the location to recording. In certain embodiments, the intensity distribution of the exposure with actinic radiation at a first wavelength can be a truncated Gaussian intensity distribution such that the intensity distribution has a lateral dimension that is less than or equal to the diameter of a Gaussian beam, d_{1/e}_{²}, measured at the 1/e² intensity point of the intensity distribution, wherein d is defined to be the diameter of the beam waist for a Gaussian intensity distribution. During subsequent recording in the volume of the said selected storage location, the lateral dimension of the exposure with actinic radiation at a first wavelength defines the lateral dimension that is activated for the overlap of the recording object and reference beams. Thus, hologram recording occurs within the overlap volume at the selected storage location, but only where the activating exposure with actinic radiation firstly occurred.

The light source providing for said illumination means can, by way of example, be a CW or pulsed or otherwise modulated laser such as a diode pumped solid state laser, or diode laser, or can be a continuous emitting or modulated light emitting diode, or a lamp or other suitable light source, or combinations thereof, and can optionally be tunable in wavelength. an optical system comprising a means for illuminating at least one selected location that has been activated for carrying out photopolymerization in the said location of the recording material, wherein the optical system providing for said illumination means for recording can comprise one or more optical elements that, by way of example, can be one or more lens, or mirrors, or waveplates, or beamsplitters or polarizers, or combinations thereof as needed for illuminating the said activated selected location with at least one wavelength for the purpose of recording at least one hologram, and the light source for the recording illumination means can be the same light source as for the illumination means to provide for the threshold or activation event or can be another suitable light source that, by way of example, can be a CW or pulsed or otherwise modulated laser such as a diode pumped solid state laser, or diode laser, or can be a continuous emitting or modulated light emitting diode, or a lamp or other suitable light source, or combinations thereof, and can optionally be tunable in wavelength.

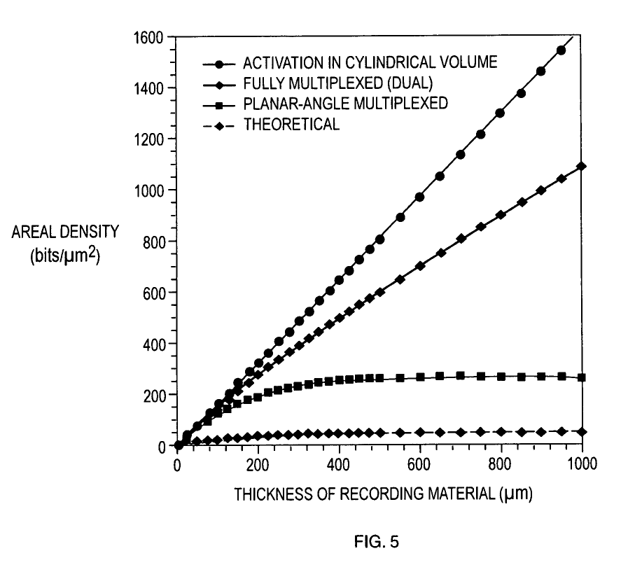

The effect of the excess lateral dimensions of the Object beam and of the Reference beam can be represented as shown in FIG. 5 as a function of increased thickness of the recording material for the parameters defined above. The plot shows the theoretical relation between achievable storage density in bits/μm² and thickness of the recording material in μm when the requirements for excess lateral dimensions of the Reference beam and Object beam are not considered for achieving optimal overlap throughout the depth of the material. FIG. 5 further shows the diminution in achievable storage density for the case of planar-angle multiplexing, when all of the dynamic range in a storage location cannot be consumed due to the limitations imposed by Bragg selectivity criteria as a function of thickness of the recording material, and additionally for the case of dual multiplexing when all of the dynamic range can be consumed in a storage location for a value that linearly scales as 5/200 μm thickness.

Thus, the achievable cumulative grating strength for the ensemble of multiplexed volume holograms recorded in a selected storage location is undesirably substantially reduced from what otherwise could be achieved if excess lateral dimensions were not required for proper overlap of the Reference and Object beams in the interaction volume of the storage location, and, further, the scaling of achievable storage density versus thickness of the recording material, Tₚₕ, is clearly not linearly increasing with the thickness, Tₚₕ, as otherwise expected from the theoretical relation between cumulative grating strength, storage density and thickness.

A preferable method for photoinitiation of polymerization during recording volume holograms, in accordance with the method and apparatus of the present invention, is to threshold or activate the holographic recording events by (i) providing for a recording material that is otherwise not sensitive or is inactive to the recording and/or reading wavelength(s) until the threshold or activation event has occurred, and (ii) further providing a means to create and/or control the amount of the photoinitiator or sensitizer compound(s) that is formed in the recording material in one or more selected storage locations in an induced activation event prior to and/or at the time of recording, for the expressed purpose of activating photoinitiation processes that can be used to initiate polymerization reactions during the recording of holograms, or otherwise activate polymerization reactions for recording of holograms, particularly in the case of thicker materials, wherein the said created amount (i.e. concentration) is at least the amount of the photoinitiator or sensitizer compound required for any specific holographic recording exposure or desired grouping of exposures that record at least one hologram(s) at the recording wavelength, such as in a grouping of multiplexed recording events.

For example, it is desirable to threshold or activate the hologram recording process in one or more selected locations so that the recording material is substantially insensitive or inactive to the recording or reading laser light wavelengths in said one or more selected locations unless and until the said threshold or activation event has occurred in said locations. In this manner reading from media that is not fully recorded (i.e. chemistry of recording can still occur), such as reading from storage locations previously recorded along an i^{th} track when recording can still be carried out elsewhere on the i^{th} track or in another track or location that may be abutting or at least partially overlapping or otherwise affected by light incident from scattered light, fluorescence, stray light, oversized area of illumination compared to the area of the stored information, or other sources of incident light that arise during recording at and/or reading from said locations in the i^{th} track, does not alter the ability to record or write information later in locations along the i^{th} track or proximal tracks of said media.

Additionally, during recording at least portions of the Reference beam light are typically incident upon the recording location at an oblique angle(s) and the cross-section area illuminated by the Reference beam should preferably be at least the size of the cross-section area illuminated by the Object beam throughout the interaction volume of the selected storage location. Consequently, the reference beam covers an area at or near the front of the recording material that is displaced laterally from the area it exits or impinges upon at the opposing surface of the said recording material. The effect of the said lateral displacement, as described above, is that the Reference beam is preferably oversized relative to the Object beam such that the cross-section area of its illumination overlaps the cross-section area of illumination of the Object beam at all depths throughout the said recording material in which the recording is to occur. Similarly, if the Object beam is incident upon the recording material at angles more oblique than the Reference beam then the Object beam is preferably oversized relative to the Reference beam.

In the general case of linear absorber compounds used for photoinitiation reactions in holographic recording materials, the oversized Reference or Object beam causes photosensitization and thus initiation of polymerization reactions to take place in a cross-section area that is larger than the cross-section area corresponding to the holographically stored information at substantially all depths in the selected storage location in which the recording is to occur. The undesired polymerization reactions in the volume of the selected storage location wastes chemistry that can otherwise be utilized for formation of holograms at one or more storage locations, so as to maximize areal density in said locations, and, consequently, the undesired reactions can reduce recording sensitivity and achievable dynamic range, and thus substantially limit the attainable storage density. This undesirable effect is exacerbated as thickness of the recording material is increased.

The present invention is a method and apparatus for photoinitiating polymerization or otherwise initiating polymerization for holographic recording in one or more selected locations in a recording media such that the initiation of polymerization reactions for recording holograms in said locations exhibits a threshold to the recording wavelength(s) provided by the optical system of the apparatus. One aspect of the present invention is that the one or more selected locations in the recording media are substantially insensitive or inactive to the wavelength of recording laser light provided by the optical system of the apparatus unless and until the threshold event for sensitizing the medium to the recording wavelength(s) has firstly occurred in the one or more selected locations. Herein, the term “insensitive” or “inactive” shall mean a chemical state of the medium, such as a photochemical state of the medium, or conformational state of molecular compounds in the medium, or other chemical or physical chemical structural state of components of the medium, in which photoinitiation of polymerization of the polymerizable compounds in one or more selected locations in the recording material for recording holograms is substantially insensitive or inactive to light at the recording wavelength(s) that is incident said locations unless the threshold or activation event that results in activating the medium so that polymerization events can be initiated using the wavelength(s) of the recording laser light to record holograms has firstly occurred. By way of example, the threshold or activation event of the present invention and the recording events for recording holograms may occur sequentially or simultaneously in a selected storage location in the recording medium, or may occur sequentially or simultaneously in a grouping of selected storage locations in the recording medium. By way of example, the required said threshold event for creating an active chemical state in at least one selected location in the recording medium for sensitizing the selected volume in the recording medium to record holograms at the recording wavelength(s) provides the means to prevent or otherwise substantially mitigate the effects of the excess lateral dimension of the Reference beam and, optionally the Object beam, from diminishing the areal information density that is achievable if such said excess dimension did not occur and, further, prevent or substantially diminish undesirably consuming monomer intended for polymerization reactions that are optimally for recording holograms.

The threshold event for sensitizing the medium to the recording wavelength(s) can preferably occur by use of light and/or heat for in-situ creation of the desired population of the active compound(s) in the volume of a selected storage location, said created active compound to be subsequently utilized for the process of photoinitiation of polymerization or other means of initiation of polymerization at the recording wavelength in the said volume of said storage location so as to provide a means for recording holograms at the recording wavelength. By way of example, but without limitation of the present invention, the in-situ created active compound resulting from the said threshold or activation event can act as a linearly absorbing dye compound for photoinitiating polymerization reactions for the purpose of recording holograms, such as, for example, by the methods of free radical, cationic, anionic or step polymerization reactions. Alternatively, the in-situ created active compound resulting from said threshold event can act directly, such as, for example, by formation of a compound capable of acting as an acid or base or radical initiator, to initiate polymerization reactions for recording holograms in the selected storage location. Preferably, but not required, the population or concentration of the in-situ created active compound is both controllable by the threshold or activation event and, additionally, relates to the subsequent recording sensitivity in the selected storage location. The selected storage location for inducing the threshold event for in situ creation of the active compound may be a location at any position in the recording media, that, by way of example, can be any position about the area of the media such as any position along a tangential, radial or helical direction, or row or column direction, and, further, the induced threshold event at said selected location may occur throughout the thickness of the recording material at the selected location, or at any thickness location or position within the recording material that includes a thickness that is less than the thickness of the recording material such as may be desired for recording information in one or more layers in the recording material.

If the induced threshold event for in-situ creation of the active compound at a selected location in the recording media occurs throughout the thickness of the recording material, then the population or concentration of the in situ created compound can be substantially uniform throughout the thickness of the recording material or, alternatively, can be non uniform such as, for example, to compensate for the transmission function of the recording light that propagates through the recording material and may be used during recording of one or more holograms at the selected storage location. The size of the selected location in the recording material for inducing the threshold or activation event for in-situ creation of the active compound may be a size that is equal to or substantially similar to the desired area of the selected storage location for recording one or more holograms, or the size may be an area that is larger or smaller than the desired area of the selected storage location for recording one or more holograms. If the threshold or activation event occurs by use of light incident upon one or more selected locations of the recording medium, then the wavelength of light for inducing the threshold or activation event is preferably different from the wavelength used for recording or reading the holograms, so that illumination of a selected storage location that is not firstly prepared or activated by the said threshold event results in substantially no polymerization reactions for recording holograms.

A grouping of other advantages can be realized by the method and apparatus of the present invention. For example, by providing for inducing or creating the said threshold or activation event at a selected location(s), the storage system can further provide for direct read after write capability to verify recording of holograms with suitable diffraction efficiency and/or signal-to-noise characteristics, such as may be desired for purposes of error checking, alignment tracking or checking, in-situ evaluation of recording sensitivity and/or remaining dynamic range in a storage location, adjustment of exposure times or intensity of exposure, and the like. Further, the design of apertures for defining lateral dimensions of recording area at a storage location and/or reading from one or more storage locations can be substantially simplified. Said apertures of the apparatus and method of the present invention may be different sizes for the illumination wavelength(s) used for the threshold or activation event by comparison to the illumination wavelength(s) used for recording or reading holograms. Still further, the media of the apparatus and method of the present invention can be encased or otherwise protected in a cassette or other suitable holder that is primarily used to protect it from dust, dirt, particulate, scratching, etc., rather than from exposure to light having the recording or reading wavelength.

Still further, the recorded holograms by way of the induced said threshold event can exhibit improved uniformity of refractive index modulation achieved during recording as a function of depth into the volume hologram, particularly for thick recording materials on the order of 500 microns or thicker. By way of example, the optical density in the volume of the storage location, whether throughout the thickness of the recording material or in one or more layers in the material, can be optionally tuned or controlled in relation to the created population of the active species for photoinitiation for each recording event or a grouping of recording events specifically for the recording sensitivity that is needed or otherwise desired for said recording event(s). For example, the in-situ tuning of the optical density for recording events at one or more selected locations can take into account the declining population of monomer in the volume of the selected location(s), as well as other consumable compounds that may be part of the photoinitiation or other initiation process for the polymerization reactions, so as to provide for more uniform recording sensitivity throughout the manifold of the grouping of multiplexed recordings in the selected storage location. Further, the threshold event for creation of the population of the active species for photoinitiation of polymerization reactions for holographic recording events can be optionally carried out from the reverse direction of the propagation direction of the Reference and/or Object beams for recording holograms, so as to further compensate for absorbance effects on intensity of transmitted light through the thickness of the recording material during recording events. The deleterious impact of exposure of the recording material to stray light during recording or direct read after write or reading of holograms in the same storage location or nearby storage locations can be substantially diminished or eliminated. Further, recording sessions can be interrupted along a recording track, whether along tangential or radial directions or other suitable directions over the surface area of the media or the thickness direction in the recording material, and may even be interrupted within a selected storage location for advantageous recording of smaller amounts information then by comparison to restrictions imposed by single recording sessions for an entire media or for recording sessions carried out along one or more tracks in tangential or radial directions or along row or column directions, or carried out in one or more layers or in one or more directions within one or more layers.

One embodiment of the method and apparatus of the present invention is to threshold or activate volume holographic recording by providing for a recording material that is otherwise not sensitive to the recording and/or reading wavelength until the threshold or activation event has occurred, and to control the amount formed of a sensitizer compound or other compound, in one or more locations in the recording media, to the amount of an active compound that is needed for any specific multiplexed holographic exposure or grouping of exposures for recording holograms at the recording wavelength, wherein the holograms can be recorded throughout the thickness such as for the case of binary data page holograms or, alternatively, in an increment of thickness such as corresponding to the double Rayleigh length that relates to the thickness of micro-localized gratings.

By way of example, heat and/or a first wavelength can be used to activate or pre-sensitize the recording media in the volume of a selected storage location that is to be used subsequently for one or more recording events, and the media can, preferably, be substantially insensitive or inactive to the recording wavelength until the threshold or activation event occurs. The threshold or activation event can comprise application of heat and/or illumination of the recording media at the one or more desired selected storage locations, such as with a diode laser, light emitting diode, diode pumped solid state laser, flash lamp and the like, that outputs light at a first wavelength or grouping of first wavelengths hereinafter referred to as first wavelength. By way of example, the apparatus and method of the present invention can provide illumination with a diode laser, light emitting diode, diode pumped solid state laser or flash lamp at a first wavelength and can, by way of example, use one or more lens elements or one or more reflective optical elements, or combinations thereof, or other suitable optical components including, for example, beamsplitters, waveplates, gratings, dichroic films, optical filters, polarizers and the like to provide said illumination.

Said first wavelength can be longer or shorter than the wavelength used for hologram recording or reading, such that substantially no absorbance exists at the recording or reading wavelength at the selected location for active initiation of polymerization reactions prior to the induced threshold or activation event, or optionally only nominal low absorbance exists near the recording or reading wavelength prior to the threshold event, wherein the said nominal low absorbance can only result in slow photoinitation induced polymerization or other initiation induced polymerization reactions, or substantially incomplete polymerization reactions at the recording or reading wavelength. In one embodiment, the threshold or activation event can comprise illumination at a combination of 1^{st} wavelengths, such as in a stepwise fashion, or, alternatively, simultaneously such as emitted, by way of example, from a light emitting diode or flash lamp or from two or more light sources that output light of different wavelengths, wherein the 1^{st} wavelengths are longer or shorter than the recording or reading wavelength such that substantially no absorbance exists at the recording or reading wavelength, prior to the threshold or activation event, that can activate initiation of polymerization, or only nominal low absorbance exists near the recording or reading wavelength prior to the threshold event such that substantially no photoinitation induced polymerization, or relatively slow photoinitation induced or other initiation induced polymerization reactions occurs at the recording or reading wavelength, or substantially incomplete polymerization reactions occur at the recording or reading wavelength.

The shape of the exposed area at a selected storage location when illuminated by the 1^{st} wavelength to induce the threshold or activation event for formation of the desired photoinitiation or initiator compound can be a circle or square or rectangle or diamond or oval or other suitable shape. In FIG. 3(b), by way of example, the area at the Fourier plane for recording data page holograms in the recording material (8) will be W² as it will be a square of dimension W on all sides corresponding the Nyquist aperture. The exposed area at the top or bottom surface of the recording material (8) can similarly be a square of area W², and the illumination at the said 1^{st} wavelength can propagate through the depth of the recording material (8) so as to have a uniform cross section area of W² at all depths within the material, as shown in FIG. 4. This can be achieved, for example, by use of collimated illumination for said 1^{st} wavelength. Alternatively, the exposed area can be within the material at a certain depth position in the material, and can extend through the depth dimension by an amount that exceeds the lateral dimension of the exposed area but is less than the total thickness of the recording material, such as would be the case for recording micro-localized gratings wherein the lateral dimension of the exposed area for a typical micrograting is on the order of about 200 nm to 1000 nm.

In another aspect of the present invention, the direction of said illumination at said 1^{st} wavelength for the threshold or activation event can be the same direction as the propagation of the Object beam and/or Reference beam used during recording of the volume holograms in the storage location. Alternatively, the direction of the said illumination at said 1^{st} wavelength for the threshold or activation event can be in the opposing direction to the propagation direction of the Object beam and/or Reference beams so as to provide for formation of a concentration profile of the photoinitiation compound created by the threshold event, said profile being in the reverse direction of the transmission function occurring during recording holograms. Further, in still another aspect of the present invention, the cross section area of the illumination at the said 1^{st} wavelength at a storage location can match the profile of the Object beam through the recording material. In FIG. 5, plotted with symbol (♦), is the relation between achievable storage density in bits/μm² and thickness of the recording material in μm when a threshold or activation event is utilized with illumination at a said 1^{st} wavelength that has uniform cross section area throughout the thickness of the recording material that equals the area at the Fourier plane for the Nyquist aperture. The effect of the said threshold event on achievable storage density versus thickness of the recording material is to substantially increase the storage density from what is otherwise achieved when no method of threshold event is used.

A recording material of the present invention can, by way of example, comprise a uniformly dispersed dye compound, or a dye compound adsorbed to the surface of a particle, such as a nanoparticle or core-shell particle that is dispersed in the material. Said dye compound, by way of example, can be a Near Infrared (NIR) dye or Infrared (IR) dye compound that absorbs NIR or IR light, respectively, or can be a compound that absorbs in the short to middle range of visible wavelengths (i.e. about 380 nm to 620 nm) such as, by way of example, a compound comprising at least one substituted or unsubstituted napthalene or anthracene or phenanthrene, or pyrene or naphthacene grouping, wherein the conjugation length of the said substituted or unsubstituted groupings can be optionally extended by way of donor/acceptor chemical structure or functionality or by at least one substituted or unsubstituted ethynyl or ethenyl grouping, or at least one substituted or unsubstituted bisethynyl or bisethenyl grouping, or at least one substituted or unsubstituted phenyl or thiophene or furan or pyrrole or pyridine grouping, or the compound can absorb in the long visible wavelengths (i.e. about 620 to 750 nm) such as a compound comprising at least one substituted or unsubstituted pentacene grouping. Further, the dye molecule can be part of a larger molecule comprising chemical structure that undergoes other chemical or photochemical or steriochemical or conformational processes or changes, including, by way of example, changes in molecular or chemical structure such as geometric isomerization and rearrangement, ring opening, ring closure, formation of cyclic products or intermediates including bicyclic products, such as by cycloaddition reactions, wherein said processes or changes, by way of example, can be related to the wavelength and/or intensity of light that illuminates the recording material at the selected location(s) and said processes or changes may, optionally, be reversible or partially reversible between two or more chemical or photochemical or structural states.

In one embodiment, the recording material of the present invention comprises a compound that can be chemically or structurally altered by exposure of one or more locations in the recording material to UV, or visible, or NIR or IR radiation, or combinations thereof, such as in a stepwise process, or alternatively simultaneously, so as to form the desirable active species during the threshold or activation event for photoinitiation of polymerization or other initiation of polymerization in the recording material at the recording wavelength. By way of example and without limitation, decomposition products can optionally form from the said compound, such as by photochemical or thermolysis processes, preferably in a short time interval (e.g. μsec or less) after exposure to said first wavelength(s). Said decomposition products can, for example, be formed in-situ at one or more selected locations in the recording medium due to oxidation reactions of the compound, that may be a dye molecule, or oxidation/reduction reactions that can involve one or more other compounds or thermolysis events. In one aspect of the current invention, the formation of the active species for photoinitiation of polymerization in the recording material at the recording wavelength can, alternatively, occur due to presence of oxygen, or to reducing or substantially eliminating the presence of oxygen, or to reducing or substantially eliminating the population of other molecule(s) that can act as a retarder(s) or inhibitor(s) to slow or prevent photoinitiation processes for initiating polymerization in the one or more selected locations of the recording material. The compounds that act as a retarder or inhibitor may additionally be diffusible in the recording medium. In one aspect, oxidation/reduction reaction(s) of the compound can occur due to reactions with a suitable photoacid generator that does not form sufficiently strong acid for initiating photopolymerization of siloxy silane epoxy compounds or vinyl ethers and the like.

Said decomposition products, by way of example, can comprise different chemical compounds or molecular structures that absorb light at a said second or third wavelength that can be the recording wavelength used for hologram formation in the recording material. Photochemical excited state structures of the decomposition products can optionally participate in oxidation/reduction reaction(s) with available photoacid generator molecules, such as Iodonium or Sulfonium or Phosphonium or Ammonium onium salts that can optionally comprise substantially non nucleophillic counter ions, so as to provide for formation of cationic chain initiation events for polymerization in the regions of constructive interference formed in the interference pattern that is generated at the second wavelength or third wavelength. Alternatively, the said onium salts or other initiator compounds can also be part of a chemical structure comprising the active species formed during the threshold or activation event so as provide for efficient photoinitiation of polymerization at the recording wavelength in one or more selected locations of the recording material. Further, photochemical excited state structures of the decomposition products formed during the threshold event can alternatively initiate free radical polymerization or anionic polymerization reactions for hologram formation at the one or more selected locations in the recording material.

The amount of the in-situ formed absorber species that is formed during or after exposure to said 1^{st} wavelength can preferably be tuned or controlled to the amount required to achieve suitable recording sensitivity for a particular exposure fluence, or tuned or controlled for the population of monomer that can polymerize in the volume of the interaction volume of the Object and Reference beam wherein the population can change during a sequence of recording events utilizing co-locational multiplexing, or tuned or controlled for the population of other compounds that can participate in the photoinitiation process for polymerization reactions in the said interaction volume, and the like, such as in a sequence of multiplexed holographic recordings. This metering process for in-situ formation of the active compound, implemented by intensity and/or time conditions for the exposure with the said 1^{st} wavelength, can be particularly advantageous for achieving high fidelity in thicker recording materials. It can also provide for direct read after write capability, such as may be used for evaluating BER of recorded holograms, and can be advantageous for achieving more uniform recording sensitivity during a sequence of multiplexed recording event, as well as tuning or controlling other holographic performance attributes.

By way of example, trimethylsilyl bis ethynlpentacene dissolved in hexane has 3 absorbance peaks in the visible region centered at about 540, 580, and 635 mm with increasing values of extinction coefficient, respectively. Upon exposure to visible light, such as white light or a single frequency laser source at about 638 nm, the absorbance at the aforementioned wavelengths declines in monotonic fashion as the medium photobleaches, and three new absorbance peaks appear that are centered at about 422, 397, 375 nm. These new violet and far UV absorbance peaks grow monotonically in a concomitant relation with the aforementioned decline in absorbance, and their presence is attributed to formation of decomposition products of the pentacene structure that have shortened conjugation length. The presence of the new absorbance peaks provide for appreciable gated recording sensitivity at violet wavelengths such as between 400 and 410 nm. Similarly, dye molecules with absorbance peaks in the near IR region, upon formation of decomposition products, can result in absorbance peaks in the green to violet wavelength regions of the visible spectrum. This would be particularly convenient due to the low cost laser diode sources that are available for NIR wavelengths and can be used for illuminating the selected locations in the recording material at the said 1^{st} wavelength for form the active compound in the volume of illumination.

Alternatively, compounds for the threshold event can absorb short wavelength radiation, such as UV radiation, that causes chemical structure change and formation of a new compound that absorbs at the recording wavelength or some other visible wavelength that can be additionally be used for illumination of the volume at the selected storage location and thereby create the compound for photoinitiation or other initiation of polymerization at the recording wavelength. Still further, the compound formed from the threshold or activation event can optionally be reversibly converted back to the species that is inactive at the recording wavelength, and then converted again by another threshold or activation event to the compound that can photoinitiate or otherwise intitiate polymerization during hologram recording.

In one embodiment of the apparatus and method of the present invention, the same optical system, or portions of the same optical system, used for delivering the Object beam to the selected location(s) in the recording material can be used for delivering the irradiation from the said 1st wavelength that is used for activation. A longer 1st wavelength would result in longer focal length due to dispersion of the refractive index of the glass materials used for optics, but the spot sizes would not differ significantly for the two wavelengths for suitable optical designs. Similarly, a shorter 1^{st} wavelength would result in shorter focal length due to said dispersion. Alternatively, a separate optical element or optical system or portion of an optical system can be used for delivering the said 1^{st} wavelength to a storage location for the threshold or activation event. Still further, in another aspect of the apparatus and method of the current invention, the threshold or activation event can be carried out as part of a servo system, such as used for tracking, addressing and/or alignment, that can optionally interact with the media at locations forward of the recording events such that activation occurs prior to recording. An optical system of the apparatus of the present invention can be designed advantageously with approximately equal focal lengths for both wavelengths, or to provide for a correction using one or more other optical elements so that when the two wavelengths are coupled in the same optical path then the focal distances would be similar for optimizing the similarity of the areas of illumination.

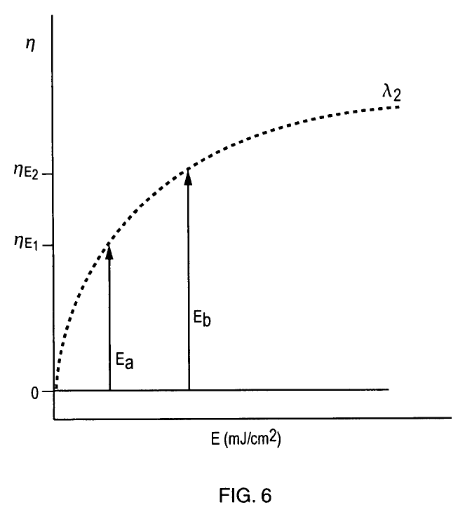

FIG. 6 is a plot showing diffraction efficiency, η, as a function of recording exposure energy E. Diffraction efficiency, η, in a selected location in the recording material does not change and is nominally a value of zero as a function of exposure energy at a recording wavelength λ₂ until an activation event occurs at the selected location at the activation or threshold wavelength λ₁. Further, η, in the selected location in the recording material does not change and is nominally a value of zero as a function of exposure energy at the said activation wavelength λ₁. Once suitable exposure has occurred at the activation wavelength λ₁ to create or otherwise induce the threshold or activation event required to record one or more holograms at the selected location, then holographic exposure at the recording wavelength λ₂ can form hologram(s) that exhibit a value of η that is related to the magnitude of the exposure energy at the recording wavelength λ₂. Thus, η_{E}_{₁} and η_{E}_{₂} can represent two values of η achieved for two values of recording exposure energy Eₐ and E_{b}, respectively, in mJ/cm² wherein E_{b}>Eₐ and the exposure energy Eₐ and E_{b} occur at the recording wavelength λ₂.

Further, the magnitude of exposure in mJ/cm² at the activation or threshold wavelength λ₁ can influence the magnitude of η achieved at the recording wavelength λ₂ for two values of activation exposure energy Eₐ and E_{b} at the activation wavelength λ₁. For example, if activation exposure energy at wavelength λ₁ for purposes of activation at a selected location forms a compound having a population that is sufficient to activate polymerization at wavelength λ₂, but only for recording a portion of the whole dynamic range of the material at the selected location on the basis of the population of monomer that can polymerize if full activation was achieved, then, by way of example, a diffraction efficiency of η≦η_{E}_{₁} can occur for an energy of Eₐ for the activation or threshold event for the range of exposure energy at the recording wavelength λ₂. Similarly, if the exposure energy at λ₁ is E_{b} for the activation or threshold event, and E_{b} provides for an activation state at a selected location that is greater than the activation state provided for by Eₐ, but the formed compound has a population that is insufficient to fully activate polymerization at wavelength λ₂ on the basis of the population of monomer that can polymerize if full activation was achieved, then a diffraction efficiency of η≦η_{E}_{₂} can occur for an energy of E_{b} for the activation or threshold event for the range of exposure energy at the recording wavelength λ₂.

### EXEMPLIFICATION

### Example 1

### In Situ Thermal Activation of a Endoperoxide Compound

### Objective

To test a medium comprising a polymerizable monomer and dye compound that is inactive to a recording wavelength to determine (1) whether the inactive dye, Rubrene-endoperoxide (REP), can be thermally converted to Rubrene while dissolved in a photo-polymerizable formulation without inducing polymerization reactions; and (2) whether the thermally generated species can be used as a photosensitizer for polymerization such as cationic ring-opening polymerization (CROP).

In order to test the efficacy of using REP as a precursor to thermally generated rubrene photosensitizer, it must be firstly shown that the REP is inactive as a photosensitizer at a first wavelength λ₁, wherein rubrene ordinarily is active, namely at λ₁=523 nm.

Additionally, it should be shown that REP, as part of a photo-polymerizable formulation, can be converted to rubrene, via a thermal activation step, without causing premature polymerization of the formulation during the said activation step.

Finally, it should be shown that after thermal conversion of REP to rubrene the formulation should be active at λ₁=523 nm for sensitizing photo-polymerization.

In this manner the formulation comprising REP is inactive to irradiance at λ₁, such as 523 nm, then after heating to a threshold temperature of about 150° C., the formulation becomes active at λ₁=532 nm for sensitizing polymerization that can be used for hologram recording.

### Thermolytic (Activating) Event

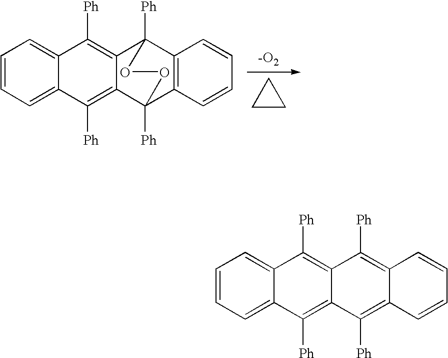

### Experimental

Rubrene-endoperoxide was prepared according to the procedure of Aubry et al, Journal of Chemical Education, Vol 76(9) 1285-1288, 1999, the entire teachings of which are incorporated herein by reference. The white powder was isolated by vacuum filtration, air dried and transferred to a clean dry vial.

A formulation was prepared using 0.001628 grams of the Rubrene-endoperoxide and 1.6249 grams of Type D, a CROP hologram recording formulation. The mixture was left to stir overnight. After the dye dissolved 0.06244 grams of triaryl-sulfonium PAG, 010-038-39 was added. PAG 010-038-39 is represented by the following structural formula:

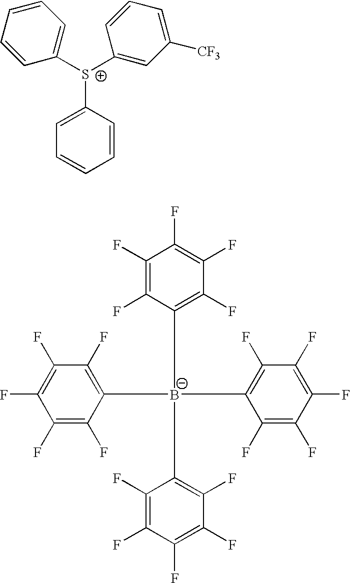

The mixture was placed on a vortex genie for 6 hours at vortex level 4. The PAG dissolved to give Formulation A as a clear and colorless oil.

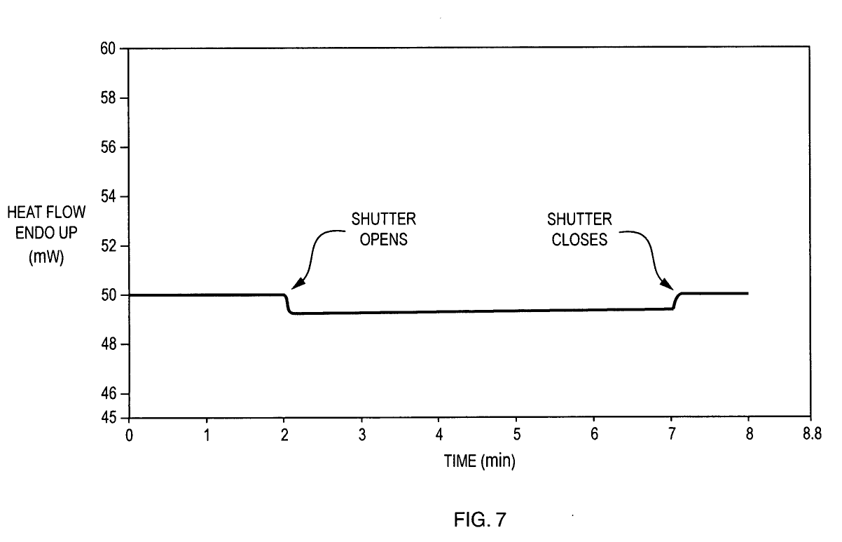

Next, an aliquot of formulation A, approximately 2.0 mg was weighed into a DSC sample pan, Pan 1. The sample pan was placed in the PDSC test compartment. The sample was subjected to a three step, eight minute experimental protocol. The first step, two minutes of shuttered no exposure establishes the baseline, the second step is initiated when a shutter opens and allow light, coupled through a fiber from a laser (Ar+ Laser λ₁, 523 nm), to irradiate the sample chamber, and the shutter stays open for a time period of 5 minutes during which the illumination is constant. The final step is the closing of the shutter to prevent illumination of the sample pan and the baseline is reestablished, this step occurring for one minute. The thermal head for the DSC was arbitrarily set for isothermal condition at 30° C. The results are shown in FIG. 7.

FIG. 7 shows experiment time in minutes plotted along the x axis and the heat of reaction in mW is plotted on the y-axis. At the 2 minute time interval the shutter is opened and light from the fiber coupled laser impinges upon the sample in the sample pan. There is a small deflection of less than 1 mW due to a small amount of heat caused by the laser light impinging on the sample pan. At the 7 minute time interval, corresponding to 5 minutes of illumination, the shutter is closed and the irradiation is terminated. The heat evolution trace returns to the baseline. Examination of the sample in the pan shows that the sample is still a clear and colorless oil, thus no apparent polymerization reaction took place that would have changed the state of the liquid to a more viscous liquid or to a solid.

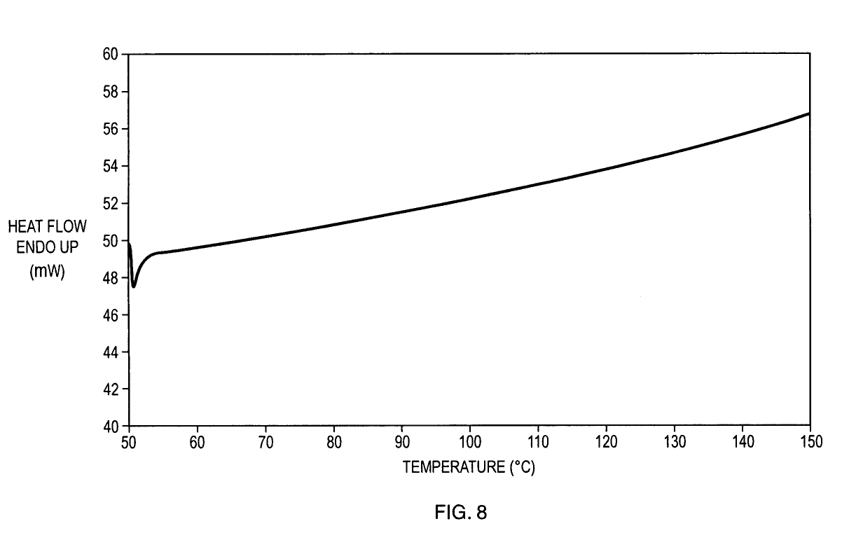

Next, Pan 1 was subjected to a thermal scan (pressure differential scanning calorimetry, PDSC) up to 150° C. at a rate of 10° C./min, followed by rapid cooling to 50° C. The result is shown in FIG. 8, which is a plot of a heat flow as a function of temperature. As can be seen, no apparent polymerization reaction took place under these experimental conditions of heating the medium to 150° C. However, the sample in Pan 1 changed color to a clear orange colored oil from a clear and colorless oil.

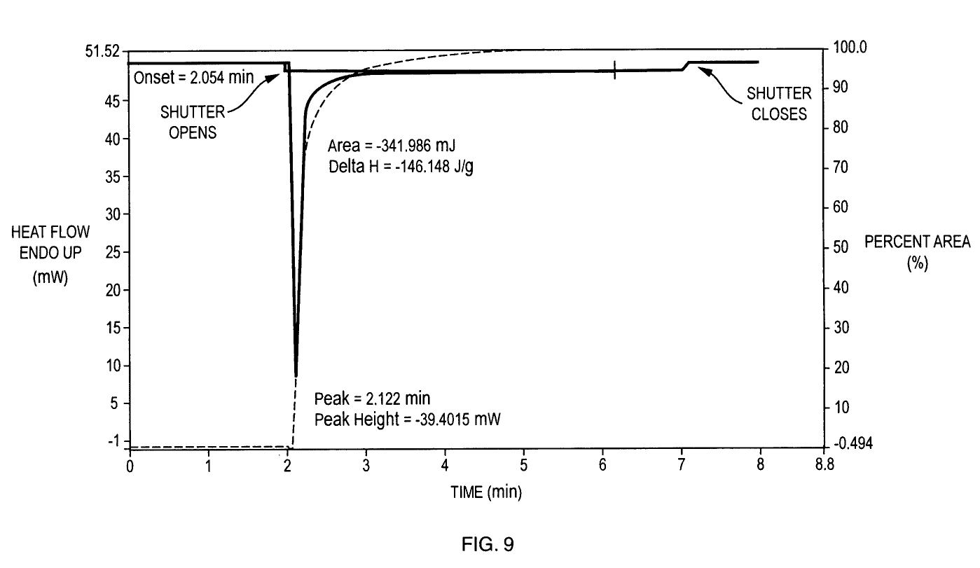

Next, the sample, Pan1, was placed back in the PDSC test compartment. The sample was re-subjected to the aforementioned three step, eight minute experimental protocol. The first step, for two minutes establishes the baseline, the second step is initiated when a shutter opens and allow light from the fiber coupled laser (Ar+ Laser λ₁, 523 nm), to irradiate the sample chamber, during which the shutter stays open for 5 minutes. The final step is the shutter being closed and the baseline of heat evolution being reestablished for a time period of one minute. The thermal head for the DSC was arbitrarily set at isothermal condition of 30° C. The results, shown in FIG. 9, are indicative of rapid polymerization being photoinitiated when the shutter is opened at 2.0 min in the aforementioned experimental profile. This sensitized polymerization at λ₁=523 nm occurs due to a photo-sensitizer compound having been created in situ during the thermal step of increasing the temperature of the medium to 150° C. Prior to the said thermal step the formulation was completely inactive to photo-polymerization with activation at λ₁=532 nm. After the said thermal cycle to 150° C. the formulation changes color and becomes activated for sensitizing photopolymerization at 532 nm.

The experiments described above show that a polymerizable media can be manufactured such that the media is insensitive to a light of certain wavelength prior to an activation event. Following an activation event, the media becomes sensitive to a light of a specified wavelength and can be polymerized or used for recording holographic data. In the instant example, the polymerizable media employs an aryl endoperoxide compound which absorbs heat (IR) and forms a sensitizer dye that absorbs at λ=532 nm.

### Example 2

### Preparation of 2-methyl-3 bromo-5(9-anthracenyl) thiophene

The target compound was prepared in 32% yield following the literature procedure, (J. Phys. Chem. A 2001, 105, 1741-1749). Purification by flash chromatography yields the pure product as a light yellow powder.

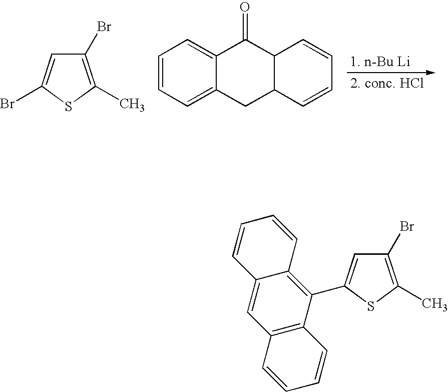

### Synthesis Molecular Switch Sensitizing Dye Compound

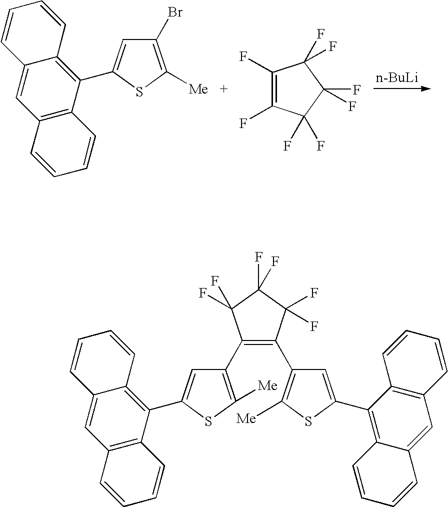

This anthracenyl molecular switch sensitizing dye compound was synthesized as per the literature procedure (J. Phys. Chem. A 2001, 105, 1741-1749) and after flash chromatography and recrystallization from hexanes the compound was recovered as a pale yellow crystalline solid.

A sample of anthracenyl molecular switch sensitizing dye compound was dissolved in hexanes. Exposure of the open “active” form of the anthracenyl molecular switch sensitizing dye compound in hexanes solution occurred with UV light, 386 nm from an LED source, forming the inactive state of the said compound, (i.e. the closed “inactive” form) that is not a desirable sensitizer for the recording wavelength. The “inactive” form of the switch dye compound is colored with a λₘₐₓ at 535 nm.

### Polymerization of Holographic Recording Medium

### Experimental:

A stock formulation was prepared comprising Type D, a CROP holographic recording formulation, and the anthracenyl molecular switch sensitizing dye compound was added in the open “active” state at a concentration of 0.05% by wt/wt., labeled Dye Stock Formulation.

The Dye Stock Formulation was subjected to irradiance of 386 nm for 30 min from an LED source to form the closed “inactive” state. HPLC analysis indicates that >90% of the anthracenyl molecular switch sensitizing dye compound is formed into the “inactive” closed state, wherein the solution is purple in color. Next, PAG, Rhodorsil® Photoinitiator 2074 was added to the purple solution to make a 6 wt/wt % mixture of PAG in the formulation. The PAG containing mixture was placed on a vortex gene for 6 hours at vortex level 4. The PAG and anthracenyl molecular switch sensitizing dye compound dissolved to give Formulation B, as clear and purple colored oil.

Next, an aliquot of Formulation B, ˜2.0 mg was weighed into a DSC sample pan, Pan 2 and placed in the PDSC test compartment. The sample was subjected to a three step, eight minute experimental protocol as described above.

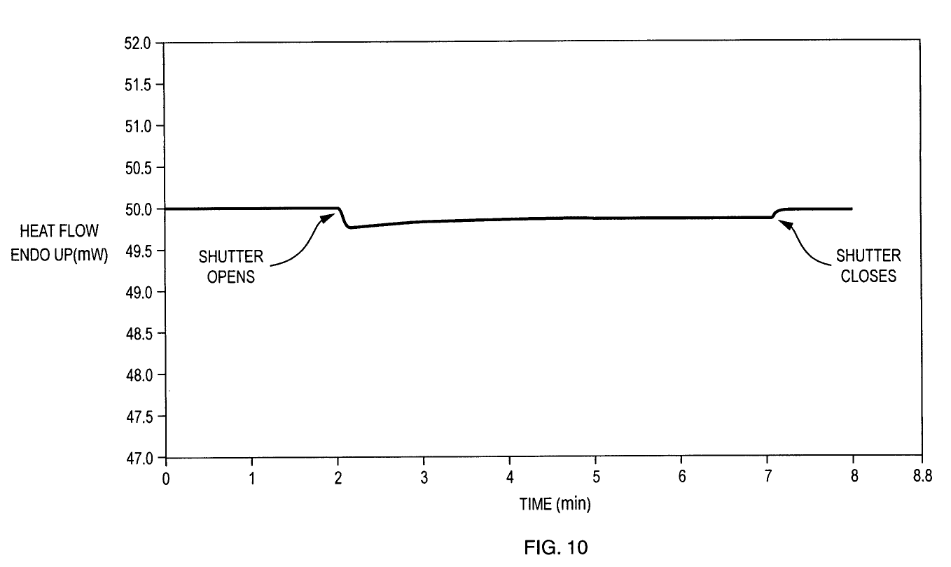

FIG. 10 shows a plot of experiment time on the x axis versus heat of reaction on the y-axis. At the 2 minute interval the shutter is opened (see label in FIG. 10) and light at 532 nm from the laser impinges upon the sample. There is a small deflection of less than 1 mW due to the absorbance of the light by the formulation and the deflection diminishes slightly as the exposure continues, indicating a reduction in the amount of absorbing species. At the 7 minute interval the shutter is closed (see label in FIG. 10) and the irradiation is terminated. The trace of heat of reaction returns to the baseline value. Examination of the sample in the pan shows that the sample changed from a purple color to a clear and colorless oil. The sample Formulation B was still a liquid demonstrating that no appreciable polymerization reaction took place.

The sample Pan 2 was next placed back in the PDSC test compartment where it was re-subjected to the three step, eight minute experimental protocol previously described. The first step, for two minutes establishes the baseline, the second step is initiated when a shutter opens and allows light at 407 nm, (100 W medium pressure Hg lamp filtered through a monochrometer), to irradiate the sample chamber, the shutter remains open for 5 minutes. For the final step, the shutter is closed and the baseline is reestablished, this step occurring for one minute.

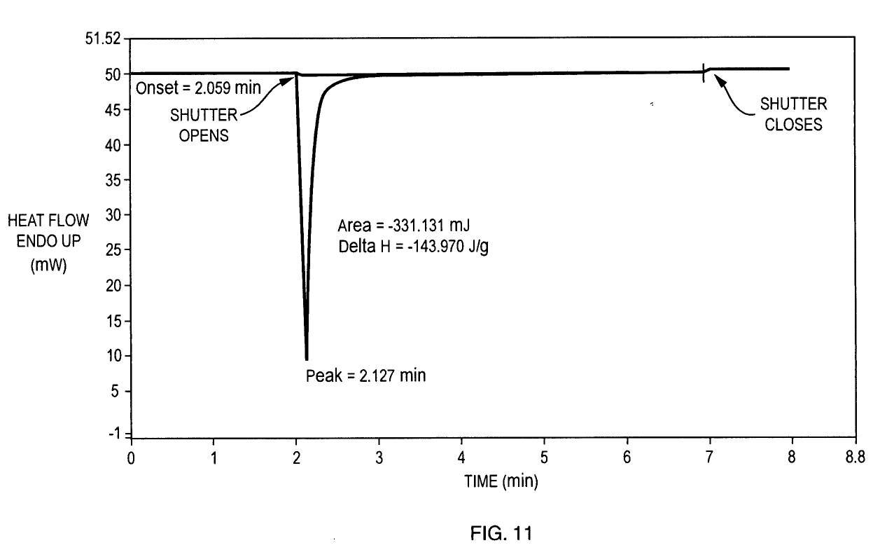

FIG. 11 shows results of experiment time on the x axis versus heat of reaction on the y-axis that are indicative of rapid polymerization kinetics (peak of exothermicity at 0.127 minutes) and large extent of polymerization reaction (144 J/g) being photo-initiated when the shutter is opened at 2.0 min in the experimental profile.

### Recording Holograms

Formulation B, comprising the anthracenyl molecular switch sensitizing dye compound in its closed “inactive” state” was sandwiched between two glass substrates with a 200 micron gap there between to form a holographic recording media having a thickness of 200 microns for the recording material. A selected location A in the media was exposed to actinic radiation at a first wavelength (532 nm) to form the active “open” state of the dye compound. Holographic recording at 407 nm, using a diode laser equipped with a temperature controlled external cavity, was carried out in the activated storage location of media using planar angle multiplexing methods with collimated signal and reference beams having intensity of 4 and 3.5 mW/beam. The observed diffraction efficiency for 3 multiplexed holograms was 34.0, 33.5 and 42.8%, respectively, corresponding to a recording sensitivity of 2.1, 1.98 and 2.0 cm/J respectively.

A comparative recording of holograms was carried out on different selected location B in the media, wherein location B was not firstly exposed to actinic radiation at a first wavelength (532 nm) for activation. Holographic recording at 407 nm was carried out in the non activated storage location of the media as above. The observed diffraction efficiency for 3 multiplexed holograms was 7.6, 10.6 and 16.8%, respectively, corresponding to a recording sensitivity of 0.97, 1.11 and 1.27 cm/J respectively, that are diminished compared to the activated location.

While this invention has been particularly shown and described with references to example embodiments thereof, it will be understood by those skilled in the art that various changes in form and details may be made therein without departing from the scope of the invention encompassed by the appended claims.

1. A polymerizable media, comprising:
at least one monomer or oligomer which undergoes polymerization;
a compound, which absorbs actinic radiation of a first wavelength and forms a sensitizer which absorbs actinic radiation of a second wavelength; and
an initiator, which, in combination with the sensitizer, initiates polymerization of the at least one monomer or oligomer when said sensitizer is exposed to actinic radiation of the second wavelength.

2. The polymerizable media of claim 1, further including an IR dye that absorbs IR radiation, thereby forming heat that is transferred to the compound.

3. The polymerizable media of claim 1, further comprising a binder, wherein chemical segregation or spatial separation of the binder from the polymerized monomer or oligomer produces refractive index modulation within the polymerizable media.

4. The polymerizable media of claim 3, wherein the produced refractive index modulation forms a hologram.

5. The polymerizable media of claim 1, wherein actinic radiation of the first wavelength is visible light.

6. The polymerizable media of claim 1, wherein actinic radiation of the first wavelength is UV light.

7. The polymerizable media of claim 1, wherein actinic radiation of the first wavelength is near infrared radiation or infrared radiation.

8. The polymerizable media of claim 1, wherein the compound is an aryl endoperoxide.

9. The polymerizable media of claim 8, wherein the aryl endoperoxide comprises a substituted or unsubstituted naphthyl endoperoxide, substituted or unsubstituted anthracenyl endoperoxide, substituted or unsubstituted naphthacenyl endoperoxide, or substituted or unsubstituted pentacenyl endoperoxide.

10. The polymerizable media of claim 9, wherein the compound is a 9,10-diphenylanthracene-endoperoxide.

11. The polymerizable media of claim 9, wherein the compound is a compound of the structural formula 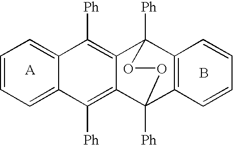
and the sensitizer is a compound having the following structural formula 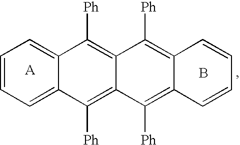
wherein rings A and B are each independently optionally substituted with one or more group selected from:
—Si(R₅)₃;
C1-C12 alkyl group, optionally substituted with —Si(R₅)₃, a C1-C12 alkoxy, a halogen, an amine, or C1-C12 alkylamine;
C1-C12 alkenyl group, optionally substituted with —Si(R₅)₃, a C1-C12 alkoxy, a halogen, an amine, or C1-C6 alkylamine;
C6-C14 aryl group, optionally substituted with —Si(R₅)₃, a C1-C12 alkoxy, a halogen, an amine, or C1-C6 alkylamine;
a 5-14-membered heteroaryl group, optionally substituted with —Si(R₅)₃, a C1-C12 alkoxy, a halogen, an amine, or C1-C12 alkylamine, and
wherein each R₅ is independently a C1-C12 alkyl, a C6-C14 aryl, or a 5-14-membered heteroaryl group.

12. The polymerizable media of claim 11, wherein rings A and B are each independently optionally substituted with one or more group selected from:
—Si(R₅)₃, C1-C12 alkyl group, a C1-C12 alkenyl group, a C6-C14 aryl group or a 5-14-membered heteroaryl group.

13. The polymerizable media of claim 11, wherein rings A and B are each unsubstituted.

14. The polymerizable media of claim 1, wherein the compound undergoes electrocyclic cyclization or retrocyclization upon exposure to actinic radiation of the first wavelength to form the sensitizer which absorbs actinic radiation of the second wavelength.

15. The polymerizable media of claim 14, wherein the compound undergoes a retro-Diel-Alders reaction.

16. The polymerizable media of claim 15, wherein the compound is represented by the structural formula 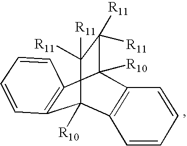
and the sensitizer is represented by the following structural formula 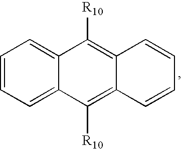
wherein
R10, for each occurrence, is independently an optionally substituted C1-C12 alkyl, an optionally substituted C2-C12 alkenyl, an optionally substituted C2-C12 alkynyl, an optionally substituted C3-C12 cycloalkyl, an optionally substituted C3-C12 cycloalkenyl, an optionally substituted C6-C14 aryl, an optionally substituted 5-14-membered heteroaryl or an optionally substituted —Si(R₆)₃, wherein each R₆ is independently a C1-C12 alkyl, a C6-C14 aryl, or a 5-14-membered heteroaryl group; and
R11, for each occurrence, is independently a C1-C12 alkyl.

17. The defined polymerizable media of claim 16, wherein the optional substituents on the group R10 are each, independently, selected from C1-C12 alkoxy, C1-C6 amine, C1-C4 alkylamine, or a halogen.

18. The polymerizable media of claim 16, wherein each R11 is, independently, a methyl or an ethyl.

19. The polymerizable media of claim 16, wherein each R11 is a methyl.

20. The polymerizable media of claim 1, wherein the compound undergoes a molecular rearrangement reaction upon exposure to actinic radiation of the first wavelength to form the sensitizer which absorbs actinic radiation of the second wavelength.

21. The polymerizable media of claim 20, wherein the compound undergoes 6π electrocyclic retrocyclization upon exposure to actinic radiation of the first wavelength to form the sensitizer which absorbs actinic radiation of the second wavelength.

22. The polymerizable media of claim 20, wherein the compound is selected from the group consisting of spiropyrans, spiro-oxazines, fulgides, triarylmethanes, naphthopyrans, diarylethenes and diheteroarylethenes.

23. The polymerizable media of claim 22, wherein the compound is a diarylethene or a diheteroarylethene, and wherein the aryl or heteroaryl moiety is selected from the group consisting of a substituted or unsubstituted phenyl, a substituted or unsubstituted naphthyl, a substituted or unsubstituted thiophene, a substituted or unsubstituted benzathiophene, a substituted or unsubstituted pyrrole, and a substituted or unsubstituted indole.

24. The polymerizable media of claim 22, wherein the ethene moiety of the diarylethene and diheteroarylethene is optionally substituted and/or is a part of an optionally substituted cycloalkene, an optionally substituted anhydride, or optionally substituted maleimide.

25. The polymerizable media of claim 24, wherein the cycloalkene moiety is a C4-C6, optionally perfluorinated, cycloalkene.

26. The polymerizable media of claim 21, wherein the compound is represented by the following structural formula: 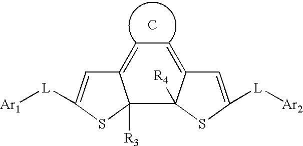
and the sensitizer is represented by the following structural formula 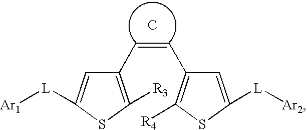
wherein:
ring C is a C3-C7 an optionally fluorinated or perfluorinated cycloalkenyl and ring C′ is an optionally fluorinated or perfluorinated C3-C7 cycloalkane;
each L is independently an inert linker;
Ar₁ is an optionally substituted C6-C22 aryl or an optionally 5-14-membered heteroaryl;
Ar₂ is independently an Ar₁, optionally substituted with an electron withdrawing group, or is an electron withdrawing group;
R₃ and R₄ are each independently selected form a C1-C12 alkyl group, a C1-C12 alkenyl group, or a C1-C12 alkoxy group.

27. The polymerizable media of claim 26, wherein the compound is represented by the following structural formula 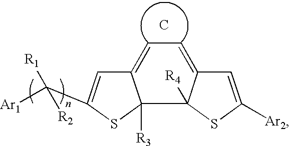
and the sensitizer is represented by the following structural formula 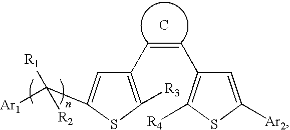
wherein:
n is 0, 1 or 2; and
R₁, R₂, are each independently selected form a C1-C12 alkyl group, a C1-C12 alkenyl group, or a C1-C12 alkoxy group.

28. The polymerizable media of claim 27, wherein the electron withdrawing group is selected from —NO2, —CF3, C1-C4 trialkylammonium, —C(O)OR′, —CN, —SO3R′, or a halogen, wherein R′ is —H or a C1-C12 alkyl.

29. The polymerizable media of claim 27, wherein ring C is a perfluorocyclopentene and ring C′ is a perfluorocyclopentane.

30. The polymerizable media of claim 27, wherein Ar₁ for each occasion is independently optionally substituted with a group represented by R^{y}, wherein R^{y} is
an optionally substituted C1-C12 alkyl, an optionally substituted C2-C12 alkenyl, an optionally substituted C2-C12 alkynyl, an optionally substituted C3-C12 cycloalkyl, an optionally substituted C3-C12 cycloalkenyl, an optionally substituted C6-C14 aryl, or an optionally substituted 5-14-membered heteroaryl or is an electron-donating group selected from C1-C12 alkoxy, C1-C4 dialkylamine, or a C6-C14 diarylamine.

31. The polymerizable media of claim 1, wherein the compound undergoes oxidation upon exposure to actinic radiation of the first wavelength to form the sensitizer which absorbs actinic radiation of the second wavelength.

32. The polymerizable media of claim 31, wherein the compound is a bis((trimethylsilyl)ethynyl)pentacene.

33. The polymerizable media of claim 31, wherein the oxidation reaction is a radically initiated oxidation reaction.

34. The polymerizable media of claim 31, wherein the compound is an optionally substituted naphthacene, an optionally substituted pentacene, an optionally substituted phenanthrene, an optionally substituted pyrene, or an optionally substituted anthracene.

35. The polymerizable media of claim 31, wherein the compound is represented by the following structural formula 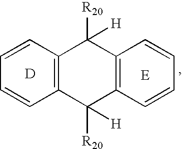
and the sensitizer is represented by the following structural formula 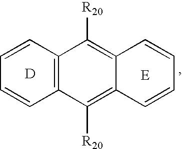
wherein
R20, for each occurrence, is independently an optionally substituted C1-C12 alkyl, an optionally substituted C2-C12 alkenyl, an optionally substituted C2-C12 alkynyl, an optionally substituted C3-C12 cycloalkyl, an optionally substituted C3-C12 cycloalkenyl, an optionally substituted C6-C14 aryl, an optionally substituted 5-14-membered heteroaryl or an optionally substituted —Si(R₈)₃, wherein each R₈ is independently a C1-C12 alkyl, a C6-C14 aryl, or a 5-14-membered heteroaryl group; and
rings D and E are each independently optionally substituted with one or more groups selected from:
—Si(R₈)₃;
C1-C12 alkyl group, optionally substituted with —Si(R₈)₃, a C1-C12 alkoxy, a halogen, an amine, or C1-C6 alkylamine;
C1-C12 alkenyl group, optionally substituted with —Si(R₈)₃, a C1-C₁₂ alkoxy, a halogen, an amine, or C1-C6 alkylamine;
C6-C14 aryl group, optionally substituted with —Si(R₈)₃, a C1-C12 alkoxy, a halogen, an amine, or C1-C6 alkylamine;
a 5-14-membered heteroaryl group, optionally substituted with —Si(R₈)₃, a C1-C12 alkoxy, a halogen, an amine, or C1-C6 alkylamine, and
wherein each R₈ is independently a C1-C12 alkyl, a C6-C14 aryl, or a 5-14-membered heteroaryl group.

36. The polymerizable media of claim 31, wherein rings E and D are each unsubstituted.

37. The polymerizable media of claim 1, wherein the compound undergoes a conformational rearrangement upon exposure to actinic radiation of the first wavelength to form the sensitizer which absorbs actinic radiation of the second wavelength.

38. The polymerizable media of claim 37, wherein the compound undergoes a cis/trans izomerization of a carbon-carbon double bond upon exposure to actinic radiation of the first wavelength to form the sensitizer which absorbs actinic radiation of the second wavelength.

39. The polymerizable media of claim 38, wherein the compound is an optionally substituted diarylethene and the compound forms the sensitizer by isomerization of the double bond.

40. The polymerizable media of claim 39, wherein the compound is represented by the structural formula 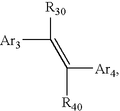
and the sensitizer is represented by the following structural formula 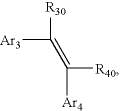
wherein
Ar₃ and Ar₄ are each independently an optionally substituted C6-C14 aryl or an optionally 5-14-membered heteroaryl;
R₃₀ and R₄₀ are independently selected from hydrogen, optionally substituted C1-C12 alkyl group, or a 5-14 membered heteroaryl.

41. The polymerizable media of claim 40, wherein R₃₀ and R₄₀ are independently selected from a 5-14 membered heteroaryl and the heteroaryl group is selected from optionally substituted thiophenyl group, optionally substituted furanyl group, optionally substituted pyrrolyl group, and optionally substituted pyridinyl group.

42. The polymerizable media of claim 1, wherein the initiator is a photoacid generator (PAG), and wherein the PAG produces acid in combination with the sensitizer.

43. The polymerizable media of claim 42, wherein the PAG is a sulfonium, iodonium, diazonium, or phosphonium salt.

44. The polymerizable media of claim 42, wherein the at least one monomer or oligomer undergoes cationic polymerization.

45. The polymerizable media of claim 44, wherein the monomer or oligomer which is capable of undergoing polymerization contains one or more epoxide, oxetane, cyclic ether, 1-alkenyl ether, unsaturated hydrocarbon, lactone, cyclic ester, lactam, cyclic carbonate, cyclic acetal, aldehyde, cyclic sulfide, cyclosiloxane, cyclotriphosphazene, or polyol functional groups, or a combination thereof.

46. The polymerizable media of claim 45, wherein the monomer is an epoxide monomer that comprises one or more cyclohexene oxide groups.

47. The polymerizable media of claim 46, wherein the epoxide monomer is a siloxane, siloxysilane comprising two or more cyclohexene oxide groups, or a polyfunctional siloxane comprising three or more cyclohexene oxide groups.

48. The polymerizable media of claim 1, wherein the initiator is a free radical generator, and wherein the free radical generator produces free radicals in combination with the sensitizer.

49. The polymerizable media of claim 48, wherein the at least one monomer or oligomer undergoes free radical polymerization.

50. The polymerizable media of claim 1, further comprising a second monomer or oligomer which is capable of undergoing polymerization.

51. The polymerizable media of claim 1, further including colloidal particles suspended in the HRM, said particles generating heat when exposed to actinic radiation.

52. The polymerizable media of claim 1, further including colloidal particles suspended in the HRM, and wherein the compound, which absorbs actinic radiation of a first wavelength, is adsorbed to said colloidal particles.

53. A method of polymerizing a polymerizable media, comprising:
in a polymerizable media that includes:
at least one monomer or oligomer which undergoes polymerization to form a polymer;
a compound, which absorbs actinic radiation of a first wavelength and forms a sensitizer which absorbs actinic radiation of a second wavelength; and
an initiator, which, in combination with the sensitizer, initiates polymerization of the at least one monomer or oligomer when said sensitizer is exposed to actinic radiation of the second wavelength,
(a) exposing a first location in the polymerizable media to actinic radiation of the first wavelength, thereby forming a sensitizer from the compound; and
(b) exposing the first location in the polymerizable media to actinic radiation of the second wavelength, thereby initiating polymerization of the at least one monomer or oligomer.

54. The method of claim 53, wherein steps (a) and (b) are repeated, and wherein, for each repetition of step (a), step (b) is repeated one or more times.

55. The method of claim 53, wherein steps (a) and (b) are performed at a second location in the polymerizable media.

56. The method of claim 55, wherein the second location is abutting or overlapping the first location.

57. The method of claim 55, wherein is the second location is neither abutting nor overlapping the first location.

58. The method of claim 53, wherein steps (a) and (b) occur substantially at the same time.

59. A method of recording a hologram, comprising:
in a holographic recording media (HRM) that includes:
at least one monomer or oligomer which undergoes polymerization;
a binder;
a compound, which absorbs actinic radiation of a first wavelength and forms a sensitizer which absorbs actinic radiation of a second wavelength; and
an initiator, which, in combination with the sensitizer initiates polymerization of the at least one monomer or oligomer, when said sensitizer is exposed to actinic radiation of the second wavelength,
(a) exposing a first storage location in the holographic recording media to a beam of actinic radiation of the first wavelength, thereby forming a sensitizer from the compound, said sensitizer absorbing actinic radiation of a second wavelength; and
(b) directing a reference beam of coherent light of the second wavelength and an object beam of coherent light of the second wavelength at the first storage location, thereby forming an interference pattern at the first storage location between the object beam and the reference beam, initiating polymerization of the at least one monomer or oligomer and thereby recording the interference pattern as a hologram within said first storage location.

60. The method of claim 59, wherein step (b) is repeated one or more times at the first storage location thereby recording multiplexed holograms in the first storage location.

61. The method of claim 59, wherein steps (a) and (b) are repeated at the first storage location, and wherein, for each repetition of step (a), step (b) is repeated one or more times thereby recording multiplexed holograms in the first storage location.

62. The method of claim 59, wherein steps (a) and (b) are performed at a second storage location in the holographic recording media.

63. The method of claim 62, wherein step (b) is repeated one or more times in the second storage location thereby recording multiplexed holograms in the second storage location.

64. The method of claim 62, wherein the second storage location is abutting or overlapping the first storage location.

65. The method of claim 62, wherein the second storage location is neither abutting nor overlapping the first storage location.

66. The method of claim 59, wherein steps (a) and (b) occur substantially at the same time.

67. The method of claim 60, wherein the multiplexed holograms are recorded in the first storage location using two or more multiplexing methods.

68. The method of claim 67, wherein the multiplexed holograms recorded using two or more multiplexing methods in the first storage location, are multiplexed with at least one multiplexing method selected from planar angle multiplexing, shift-multiplexing including co-linear shift multiplexing, phase-multiplexing, phase encoded multiplexing, azimuthal multiplexing, and out-of-plane tilt-multiplexing.

69. The method of claim 59, wherein to the beam of actinic radiation of the first wavelength, the reference beam or the object beam are produced by a source of actinic radiation that is a continuous emitting source or a pulsed source.

70. The method of claim 69, wherein the source of actinic radiation is a diode laser, and further, wherein the diode laser optionally comprises an external cavity.

71. The method of claim 59, wherein the beam of actinic radiation of the first wavelength, the reference beam or the object beam each independently has a Gaussian intensity distribution at the first storage location.

72. The method of claim 59, wherein the beam of actinic radiation of the first wavelength, the reference beam or the object beam each independently has a truncated Gaussian intensity distribution at the first location in the HRM, wherein the minimum diameter of the truncated Gaussian intensity distribution is less than or equal to the diameter of said beam, d_{1/e}_{²}, measured at the 1/e² intensity point.

73. The method of claim 59, wherein exposing the first location to the beam of actinic radiation of the first wavelength or the reference beam or the object beam exposes a volume element of the HRM having a cross-sectional area that changes as a function of depth through the HRM.

74. The method of claim 59, wherein of the beam of actinic radiation of the first wavelength, the reference beam, or the object beam is each independently generated by a tunable source.

75. The method of claim 59, wherein actinic radiation of the first wavelength is visible light.

76. The method of claim 59, wherein actinic radiation of the first wavelength is UV light.

77. The method of claim 59, wherein actinic radiation of the first wavelength is near infrared or infrared radiation.

78. The method of claim 59, wherein the hologram is a binary data page hologram.

79. The method of claim 78, wherein the data page hologram is recorded with an object beam that is amplitude modulated or phase modulated.

80. The method of claim 59, wherein the hologram is a micrograting recorded in a portion of a volume of the first storage location in the holographic recording media (HRM).

81. The method of claim 80, wherein one or more microgratings are recorded in the portion of the volume of the first storage location by repeating step (b) at the first storage location, thereby recording multiplexed microgratings that overlap at least in part in the said portion of the volume of the first storage location.

82. The method claim of 81, wherein the multiplexed microgratings are recorded with two or more different wavelengths or two or more different phases.

83. A method of recording a micrograting hologram, comprising:
in a holographic recording media (HRM) that includes:
at least one monomer or oligomer which undergoes polymerization;
a binder;
a compound, which absorbs actinic radiation of a first wavelength and forms a sensitizer which absorbs actinic radiation of a second wavelength; and
an initiator, which, in combination with the sensitizer initiates polymerization of the at least one monomer or oligomer, when said sensitizer is exposed to actinic radiation of the second wavelength,
(a) exposing a first storage location in the holographic recording media to actinic radiation of the first wavelength, thereby forming a sensitizer from the compound, said sensitizer absorbing electromagnetic radiation of a second wavelength, said first storage location being located in a portion of the depth of the HRM; and
(b) directing a reference beam of the second wavelength and an object beam of the second wavelength at the first storage location, thereby forming an interference pattern at the first storage location between the object beam and the reference beam, and initiating polymerization of the at least one monomer or oligomer in the first storage location and thereby recording the interference pattern as a hologram within said first storage location.

84. A method of recording a hologram, in a holographic recording media (HRM) that includes:
at least one monomer or oligomer which undergoes polymerization;
a binder;
a compound, which absorbs actinic radiation of a first wavelength and forms a sensitizer which absorbs actinic radiation of a second wavelength; and
an initiator, which, in combination with the sensitizer initiates polymerization of the at least one monomer or oligomer, when said sensitizer is exposed to actinic radiation of the second wavelength,
(a) exposing a first storage location in the holographic recording media (HRM) to a beam of actinic radiation of the first wavelength, thereby forming a sensitizer from the compound, said sensitizer absorbing electromagnetic radiation of a second wavelength; and
(b) directing a reference beam of coherent light of the second wavelength and an object beam of coherent light of the second wavelength at the first storage location in the holographic recording media (HRM), thereby forming an interference pattern at the first storage location between the object beam and the reference beam, initiating polymerization of the at least one monomer or oligomer and recording the interference pattern therefrom as a hologram within said first storage location,
wherein the beam of actinic radiation of the first wavelength, the reference beam, or the object beam is each independently generated by a tunable source.

85. The polymerizable media of claim 49, wherein the produced free radicals initiates free radical polymerization reactions.

86. The polymerizable media of claim 85, wherein the sensitizer is diphenylanthracene.

87. The method of claim 59, wherein the beam of actinic radiation of the first wavelength is a collimated beam.

88. The polymerizable media of claim 1, wherein the formed sensitizer is a linear absorbing dye.

89. The polymerizable media of claim 1, wherein the formed sensitizer is a non-linear-absorbing dye.

90. The polymerizable media of claim 1, wherein the amount of formed sensitizer is controlled by the intensity of the actinic radiation of a first wavelength or by the duration of the exposure of the compound to the actinic radiation of a first wavelength.

91. The polymerizable media of claim 1, wherein the actinic radiation of a first wavelength is used as a source of light for generating a servo signal from the media.

92. The method of claim 38, further including a step (c) of reading the recorded hologram after recording the hologram at the first storage location, wherein the reading step confirms the recording of the hologram at the first storage location.

93. The method of claim 49, further including a step (c) of reading the recorded micrograting hologram after recording the micrograting hologram at the first storage location, wherein the reading step confirms the recording of the micrograting hologram at the first storage location.

94. The method of claim 38, wherein steps (a) and (b) are performed at a second storage location in the holographic recording media before steps (a) and (b) or step (b) are repeated at the first storage location in the holographic recording media for recording multiplexed holograms at the first storage location.

95. The method of claim 94, wherein steps (a) and (b) are repeated at the first storage location for recording multiplexed holograms at the first storage location, after performing steps (a) and (b) at the second storage location in the holographic recording media.

96. An optical article, comprising:
two or more substrates; and
a holographic recording medium (HRM) therebetween, said HRM including:
at least one monomer or oligomer which undergoes polymerization;
a compound, which absorbs actinic radiation of a first wavelength and forms a sensitizer which absorbs actinic radiation of a second wavelength; and
an initiator, which, in combination with the sensitizer, initiates polymerization of the at least one monomer or oligomer when said sensitizer is exposed to actinic radiation of the second wavelength.
